(19) United States
(12) Patent Application Publication
(10) Pub. No.: US 2026/0096116 A1
(43) Pub. Date: Apr. 2, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Reona FURUKAWA, Tokyo (JP); Hidenori FUJII, Tokyo (JP); Koji TANAKA, Tokyo (JP); Shinya SONEDA, Tokyo (JP); Kazuya KONISHI, Tokyo (JP)

(73) Assignee: Mitsubishi Electric Corporation, Tokyo (JP)

(21) Appl. No.: 19/309,084

(22) Filed: Aug. 25, 2025

(30) Foreign Application Priority Data
Sep. 30, 2024 (JP) 2024-169970

(51) Int. Cl. H10D 12/00; H10D 12/01; H10D 64/00

(52) U.S. Cl. CPC H10D 12/415; H10D 12/038; H10D 12/481; H10D 64/117

(57) ABSTRACT

A semiconductor device includes: a channel stopper region of a first conductivity type formed on a surface layer of a drift layer in a termination region; a first termination trench formed in the drift layer in the termination region; a plurality of termination electrodes provided in the first termination trench while being surrounded by a first termination insulating film; and a channel stopper electrode provided on an upper surface of the drift layer while being electrically connected to the channel stopper region and the termination electrodes, wherein the plurality of termination electrodes include a first termination electrode and a second termination electrode.

### BACKGROUND OF THE INVENTION

### Field of the Invention

The technology disclosed in the present specification relates to a semiconductor technology.

### Description of the Background Art

In a semiconductor device, an active region and a termination region surrounding the active region in plan view are provided, and extension of a depletion layer extending from a PN junction is controlled by a termination structure provided in the termination region (see, for example, Japanese Patent Application Laid-Open No. 2013-069783).

In a semiconductor device that handles large currents, such as a power semiconductor device, it is increasingly important to finely control extension of a depletion layer according to each application.

### SUMMARY

The technology disclosed in the present specification is a technology for improving flexibility in control of a depletion layer.

A semiconductor device according to a first aspect of the technology disclosed in the present specification is a semiconductor device including an active region and a termination region surrounding the active region in plan view, and includes: a drift layer of a first conductivity type; a channel stopper region of the first conductivity type that is formed on a surface layer of the drift layer in the termination region and has an impurity concentration higher than that of the drift layer; a first termination trench formed in the drift layer in the termination region; a plurality of termination electrodes provided while being surrounded by a first termination insulating film in the first termination trench; a channel stopper electrode provided on an upper surface of the drift layer while being electrically connected to the channel stopper region and at least one of the termination electrodes; an impurity region of a second conductivity type formed on the surface layer of the drift layer in the active region; a gate trench formed in the drift layer while being adjacent to the impurity region; a plurality of gate electrodes provided while being surrounded by a gate insulating film in the gate trench; an interlayer insulating film provided so as to cover the gate trench; an upper-surface electrode provided so as to cover the upper surface of the drift layer and the interlayer insulating film; and a lower-surface electrode provided on a lower surface of the drift layer at least in the active region, in which the plurality of termination electrodes in the first termination trench include a first termination electrode and a second termination electrode, the plurality of gate electrodes include a first gate electrode and a second gate electrode, the first termination electrode and the second termination electrode are provided apart from each other in the first termination trench, and the first gate electrode and the second gate electrode are provided apart from each other in the gate trench.

According to at least the first aspect of the technology disclosed in the present specification, a plurality of termination electrodes are provided in a single termination trench, whereby flexibility in control of a depletion layer can be improved.

Meanwhile, objects, features, aspects, and advantages regarding the technology disclosed in the present specification will be more apparent from the following detailed description and the accompanying drawings.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view for illustrating an example of a configuration of a semiconductor device according to preferred embodiments;

FIG. 2 is a perspective view for illustrating an example of a configuration of a part in an active region in FIG. 1;

FIG. 3 is a sectional view for illustrating an example of a configuration taken along line B-B in FIG. 2;

FIG. 4 is a sectional view for illustrating an example of a configuration taken along line C-C in FIG. 2;

FIG. 5 is a sectional view for illustrating an example of a configuration taken along line A-A in FIG. 1;

FIG. 6 is a sectional view for illustrating another example of the configuration taken along line A-A in FIG. 1;

FIG. 7 is a sectional view for illustrating an example of a configuration taken along line D-D in FIG. 6;

FIG. 8 is a sectional view for illustrating another example of the configuration taken along line D-D in FIG. 6;

FIGS. 9 to 16 are views for explaining a method of manufacturing a semiconductor device according to the preferred embodiments;

FIGS. 17 to 23 are views for explaining a method of manufacturing a termination electrode in a termination trench illustrated in FIG. 8 in the semiconductor device according to the preferred embodiments;

FIGS. 24 and 25 are each a sectional view for illustrating another example of the configuration taken along line A-A in FIG. 1 in the semiconductor device according to the preferred embodiments;

FIG. 26 is a sectional view for illustrating another example of the configuration taken along line D-D in FIG. 6; and

FIGS. 27 and 28 are each a sectional view for illustrating another example of the configuration taken along line A-A in FIG. 1 in the semiconductor device according to the preferred embodiments.

### DESCRIPTION OF THE PREFERRED EMBODIMENTS

Hereinafter, preferred embodiments will be described with reference to the accompanying drawings. In the following preferred embodiments, detailed features and the like is also shown for the sake of description of the technology, but they are mere examples, and not all of them are necessarily essential features for making the preferred embodiments practicable.

Note that the drawings are schematically illustrated, and, for the sake of convenience in description, omission of components, simplification of configurations, or the like is made in the drawings as appropriate. Further, sizes and relative positional relationships of components respectively illustrated in different drawings are not necessarily accurately illustrated, but can be altered as appropriate. Further, in a drawing that is not a sectional view, such as a plan view, hatching may be applied in order to facilitate understanding of the contents of the preferred embodiments.

Further, in the following description, similar components are illustrated with the same reference signs in the drawings, and their names and functions are also similar. Thus, a detailed description thereof is omitted where appropriate in order to avoid duplication.

Further, in the description given in the present specification, when term, “comprising a certain component”, “including a certain component”, “having a certain component”, or the like are described, such terms are not an exclusive expression excluding the presence of another component unless otherwise specified.

Further, in the description given in the present specification, ordinal numbers such as “first” and “second”, if any, are used for the sake of convenience in order to facilitate understanding of the contents of the preferred embodiments, and the contents of the preferred embodiments are not limited to the order or the like that can be caused by these ordinal numbers.

Further, in the description given in the present specification, when something is described as “A or B”, the description includes a case where the terms mean only one of A and B and a case where the terms mean both A and B unless contradiction occurs.

Further, in the description given in the present specification, regarding the term, “positive . . . -axis direction”, “negative . . . -axis direction”, or the like, a direction along an arrow of an illustrated . . . -axis is a positive direction, and a direction opposite to an arrow of an illustrated . . . -axis is a negative direction.

Further, in the description given in the present specification, terms that mean specific positions or directions, such as “upper”, “lower”, “left”, “right”, “side”, “bottom”, “surface”, and “back”, if any, are used for the sake of convenience in order to facilitate understanding of the contents of the preferred embodiments, and are irrelevant to positions or directions in actual application of the preferred embodiments.

Further, in the description given in the present specification, when something is described as “an upper surface of . . . ” or “a lower surface of . . . ”, the description includes a state in which another component is formed on an upper surface or a lower surface of a certain component, in addition to the upper surface alone or the lower surface alone of the certain component. Specifically, for example, when “B provided on an upper surface of A” is described, the description does not preclude interposition of another component “C” between A and B.

### First Preferred Embodiment

Hereinafter, a semiconductor device and a method of manufacturing a semiconductor device according to the present preferred embodiment will be described.

### Configuration of Semiconductor Device

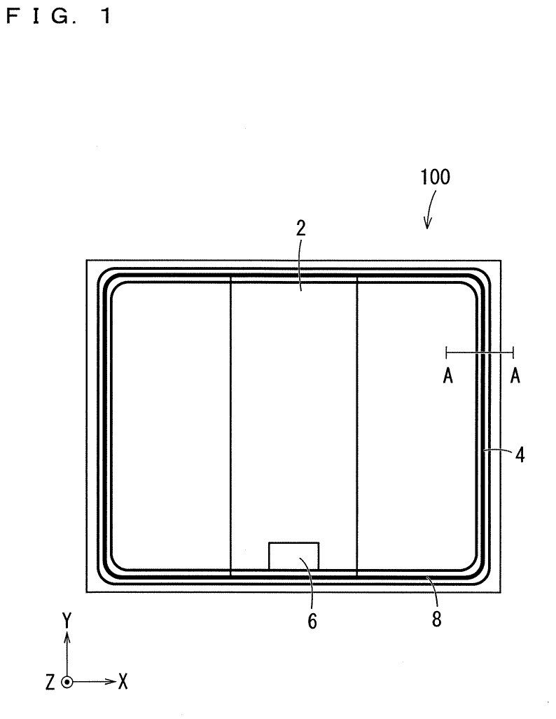

FIG. 1 is a plan view for illustrating an example of a configuration of a semiconductor device according to the present preferred embodiment. As exemplified in FIG. 1, a semiconductor device 100 includes an active region 2 and a termination region 4 that is formed so as to surround the active region 2 in plan view. A gate pad 6 is placed at an end of the active region 2. The gate pad 6 is connected to a gate wire 8 that is formed so as to surround the active region 2 in plan view.

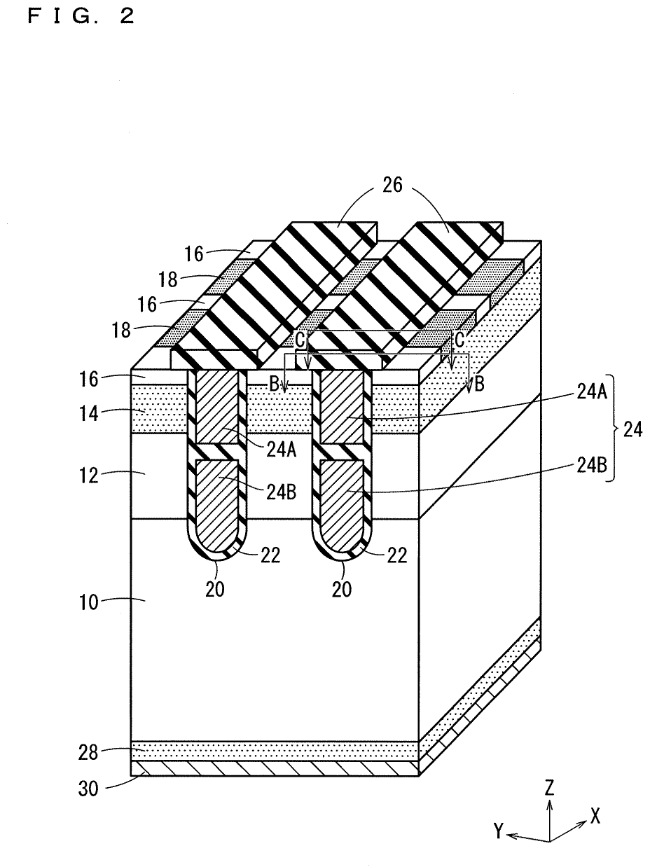

FIG. 2 is a perspective view for illustrating an example of a configuration of a part in the active region 2 in FIG. 1. In FIG. 1, illustration of electrodes formed on an upper surface of the configuration is omitted for the sake of convenience.

As exemplified in FIG. 2, the semiconductor device 100 is, for example, an insulated gate bipolar transistor (that is, an IGBT). The semiconductor device 100 includes, in the active region 2, an n-type drift layer 10, an n+-type charge accumulation region 12 formed on an upper surface of the n-type drift layer 10, a p-type channel doped region 14 formed on a surface layer of the n+-type charge accumulation region 12, an n+-type source region 16 formed on a part of a surface layer of the p-type channel doped region 14, a p+-type impurity region 18 formed on another part of the surface layer of the p-type channel doped region 14, a gate trench 20 formed so as to extend from an upper surface of the n+-type source region 16 and an upper surface of the p+-type impurity region 18 and reach the inside of the n-type drift layer 10, a gate electrode 24 placed while being surrounded by a gate insulating film 22 in the gate trench 20, and an interlayer insulating film 26 covering the gate electrode 24, a p+-type collector layer 28 formed on a lower surface of the n-type drift layer 10, and a collector electrode 30 formed on a lower surface of the p+-type collector layer.

The n-type drift layer 10 is made of, for example, Si, SiC, or the like. The n+-type charge accumulation region 12 has an impurity concentration higher than an impurity concentration of the n-type drift layer 10.

The p-type channel doped region 14 is formed by ion implantation of impurities such as boron, for example.

The n+-type source region 16 has an impurity concentration higher than the impurity concentration of the n-type drift layer 10. The p+-type impurity region 18 has an impurity concentration higher than an impurity concentration of the p-type channel doped region 14. The n+-type source region 16 and the p+-type impurity region 18 are alternately arranged, and each formed so as to extend along a Y-axis direction.

The n+-type source region 16 or the p+-type impurity region 18, the p-type channel doped region 14, and the n+-type charge accumulation region 12 are adjacent to the gate trench 20. The gate trenches 20 are each formed so as to extend along an X-axis direction and are arranged along the Y-axis direction. However, the direction in which each of the gate trenches 20 extends and the direction in which the gate trenches 20 are arranged are not limited to those in the case illustrated in FIG. 2, and a positional relationship with a termination trench described later (in other words, a combination of extending directions) is also not limited to that described in the present preferred embodiment. The gate insulating film 22 is formed on an inner wall and a bottom surface of the gate trench 20, and is formed so as to surround the gate electrode 24 in the gate trench 20.

A plurality of gate electrodes 24 are provided in a single gate trench 20. The plurality of gate electrodes 24 are provided apart from each other, and the gate insulating film 22 is interposed between the plurality of gate electrodes 24. In FIG. 2, the gate electrode 24 located on a side in a positive Z-axis direction is referred to as a gate electrode 24A, and the gate electrode 24 located on a side in a negative Z-axis direction is referred to as a gate electrode 24B.

Arrangement of the plurality of gate electrodes 24 in the gate trench 20 may be arrangement in which the gate electrodes 24 overlap each other in plan view as illustrated in FIG. 2, in other words, arrangement along the Z-axis direction, or may be arrangement along the Y-axis direction or arrangement along the X-axis direction.

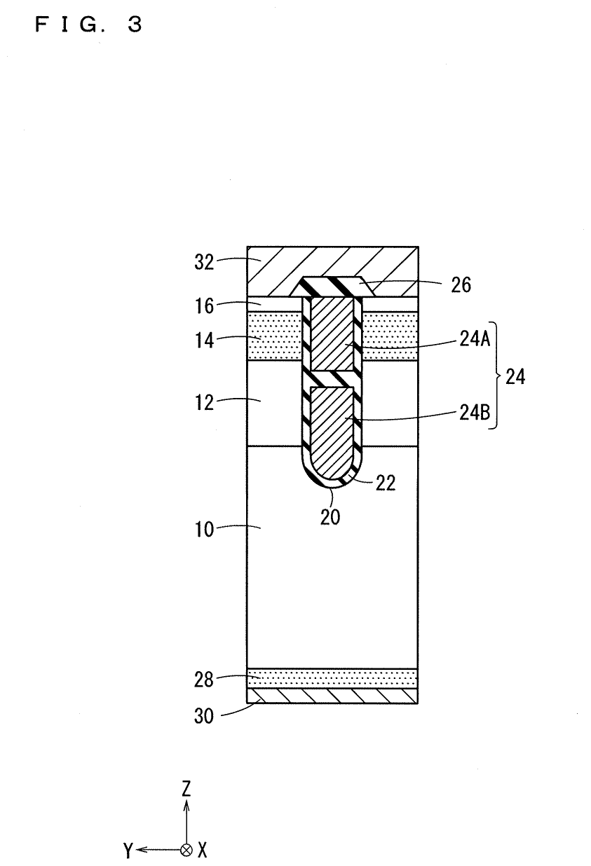

FIG. 3 is a sectional view for illustrating an example of a configuration taken along line B-B in FIG. 2. As exemplified in FIG. 3, the semiconductor device 100 includes, in the active region 2, the n-type drift layer 10, the n+-type charge accumulation region 12, the p-type channel doped region 14, the n+-type source region 16, the gate trench 20 formed so as to extend from the upper surface of the n+-type source region 16 and reach the inside of the n-type drift layer 10, the gate electrodes 24, the interlayer insulating film 26, an emitter electrode 32 covering the interlayer insulating film 26 and the n+-type source region 16, the p+-type collector layer 28, and the collector electrode 30. In FIG. 3, the emitter electrode 32 that is omitted in FIG. 2 is illustrated also.

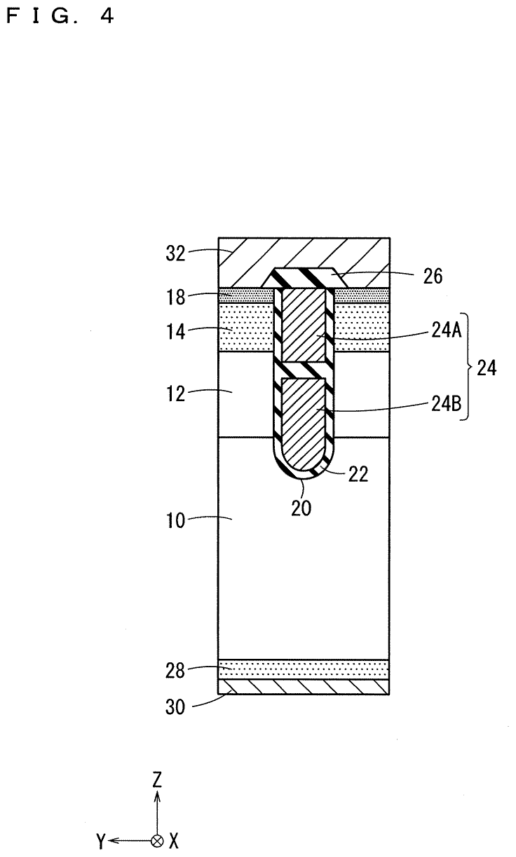

FIG. 4 is a sectional view for illustrating an example of a configuration taken along line C-C in FIG. 2. As exemplified in FIG. 4, the semiconductor device 100 includes, in the active region 2, the n-type drift layer 10, the n+-type charge accumulation region 12, the p-type channel doped region 14, the p+-type impurity region 18, the gate trench 20 formed so as to extend from the upper surface of the p+-type impurity region 18 and reach the inside of the n-type drift layer 10, the gate electrodes 24, the interlayer insulating film 26, the emitter electrode 32 covering the interlayer insulating film 26 and the p+-type impurity region 18, the p+-type collector layer 28, and the collector electrode 30. In FIG. 4, the emitter electrode 32 that is omitted in FIG. 2 is illustrated also.

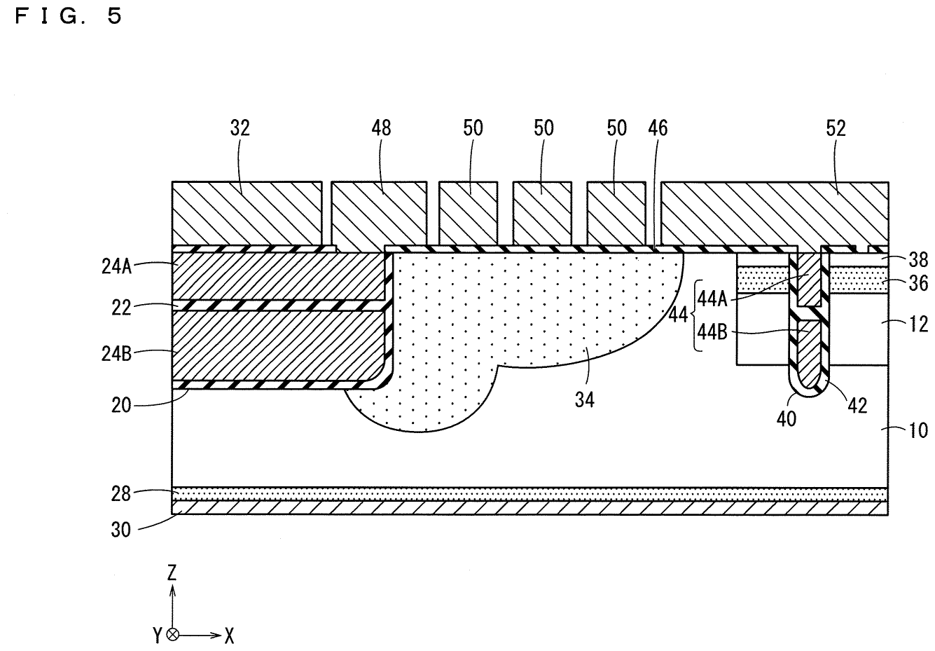

FIG. 5 is a sectional view for illustrating an example of a configuration taken along line A-A in FIG. 1. In FIG. 5, along the X-axis direction, a range in which the gate trench 20 is formed corresponds to the active region 2, and a range in the positive X-axis direction with respect to the gate trench 20 corresponds to the termination region 4.

As exemplified in FIG. 5, the semiconductor device 100 includes a p+-type impurity region 34 formed on the surface layer of the n-type drift layer 10 so as to extend from the active region 2 to the termination region 4, the n+-type charge accumulation region 12 formed on the surface layer of the n-type drift layer 10 at a position farther from the active region 2 than the p+-type impurity region 34, a p-type impurity region 36 formed on a surface layer of the n+-type charge accumulation region 12, an n+-type channel stopper region 38 formed on a surface layer of the p-type impurity region 36, a termination trench 40 formed so as to extend from an upper surface of the n+-type channel stopper region 38 and reach the inside of the n-type drift layer 10, and a termination electrode 44 placed while being surrounded by a termination insulating film 42 in the termination trench 40, a field insulating film 46 formed on the upper surface of the n-type drift layer 10 in the termination region 4, a gate electrode 48 formed so as to be in contact with an upper surface of a gate electrode 24A exposed in the gate trench 20 and extend on an upper surface of the field insulating film 46, a field plate electrode 50 formed on the upper surface of the field insulating film 46 at a position farther from the active region 2 than the gate electrode 48 while being located apart from the gate electrode 48, a channel stopper electrode 52 formed on the upper surface of the field insulating film 46 at a position farther from the active region 2 than the field plate electrode 50 while being located apart from the field plate electrode 50, the p+-type collector layer 28, and the collector electrode 30. Note that the p-type impurity region 36 and the n+-type charge accumulation region 12 are not necessarily required to be provided.

The p+-type impurity region 34 and the p-type impurity region 36 are formed by ion implantation of impurities such as boron, for example.

The n+-type channel stopper region 38 has an impurity concentration higher than that of the n-type drift layer 10. The n+-type charge accumulation region 12 has an impurity concentration higher than that of the n-type drift layer 10 and lower than that of the n+-type channel stopper region 38.

The termination trench 40 is formed so as to extend along the Y-axis direction. The n+-type channel stopper region 38, the p-type impurity region 36, and the n+-type charge accumulation region 12 are adjacent to the termination trench 40. The termination insulating film 42 is formed on an inner wall and a bottom surface of the termination trench 40, and is formed so as to surround the termination electrode 44 in the termination trench 40. The termination electrode 44 is exposed from the termination insulating film 42 in the vicinity of an upper surface of the termination trench 40, but is surrounded by the termination insulating film 42 in the termination trench 40.

A plurality of termination electrodes 44 are provided in a single termination trench 40. The plurality of termination electrodes 44 are provided apart from each other, and the termination insulating film 42 is interposed between the plurality of termination electrodes 44. In FIG. 5, the termination electrode 44 located on a side in the positive Z-axis direction is referred to as a termination electrode 44A, and the termination electrode 44 located on a side in the negative Z-axis direction is referred to as a termination electrode 44B.

Arrangement of the plurality of termination electrodes 44 in the termination trench 40 may be arrangement in which the termination electrodes 44 overlap each other in plan view as illustrated in FIG. 5, in other words, arrangement along the Z-axis direction, or may be arrangement along the Y-axis direction or arrangement along the X-axis direction.

As illustrated in FIG. 5, a plurality of field plate electrodes 50 may be formed along the X-axis direction, and each of the field plate electrodes 50 may be formed so as to surround the active region 2 in plan view. Note that the field plate electrode 50 is not necessarily required to be provided.

The channel stopper electrode 52 is formed in contact with an upper surface of the termination electrode 44A exposed in the termination trench 40, and is electrically connected to the termination electrode 44A. Further, the channel stopper electrode 52 is formed in contact with the upper surface of the n+-type channel stopper region 38 exposed from the field insulating film 46, and is electrically connected to the n+-type channel stopper region 38.

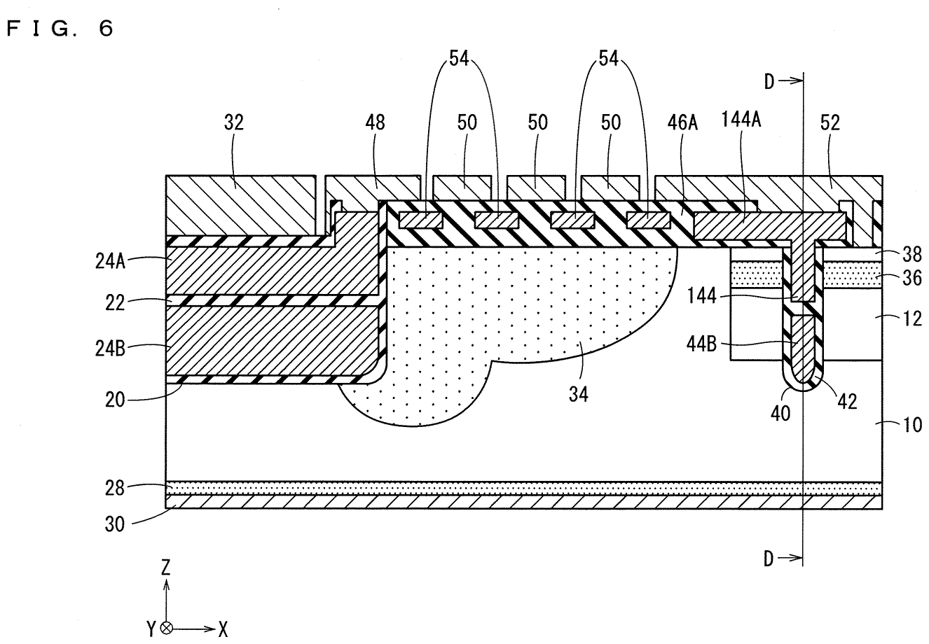

FIG. 6 is a sectional view for illustrating another example of a configuration taken along line A-A in FIG. 1. In FIG. 6, along the X-axis direction, a range in which the gate trench 20 is formed corresponds to the active region 2, and a range in the positive X-axis direction with respect to the gate trench 20 corresponds to the termination region 4.

In the example illustrated in FIG. 6, a field plate 54 is provided in addition to the components illustrated in FIG. 5. Note that, in a case where the field plate 54 is not provided as illustrated in FIG. 5, a need for a photomask for forming the field plate 54 can be eliminated.

The field plate 54 is provided on the upper surface of the n-type drift layer 10 in the termination region 4 with upper and lower surfaces and side surfaces thereof surrounded by a field insulating film 46A. The field insulating film 46A containing the field plate 54 is formed so as to have a thickness larger than that of the field insulating film 46. As illustrated in FIG. 6, a plurality of field plates 54 may be formed along the X-axis direction, and each of the field plates 54 may be formed so as to surround the active region 2 in plan view.

Further, the field plate 54 may be provided at a position between the field plate electrodes 50 in plan view.

Further, in the example illustrated in FIG. 6, a termination electrode 144 located on a side in the positive Z-axis direction in the termination trench 40 includes a connection portion 144A provided so as to extend on an upper surface of the field insulating film 46A, in other words, extend on the upper surface of the n-type drift layer 10. The connection portion 144A, like the termination electrode 144, is made of, for example, polysilicon. The channel stopper electrode 52 is in contact with the connection portion 144A of the termination electrode 144 exposed in the termination trench 40. Note that the connection portion 144A may be formed simultaneously with the field plate 54.

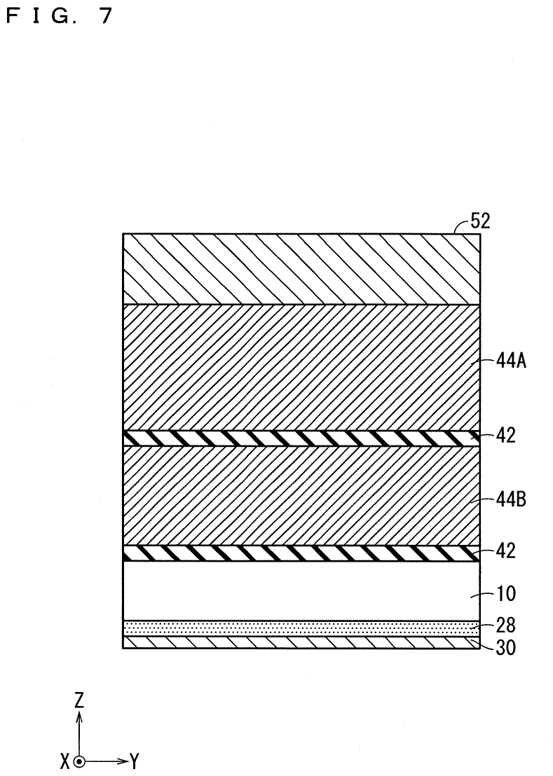

FIG. 7 is a sectional view for illustrating an example of a configuration taken along line D-D in FIG. 6. As exemplified in FIG. 7, only the termination electrode 44A may be in contact with the channel stopper electrode 52, to make both the electrodes electrically connected to each other. In this case, the termination electrode 44B is a floating electrode.

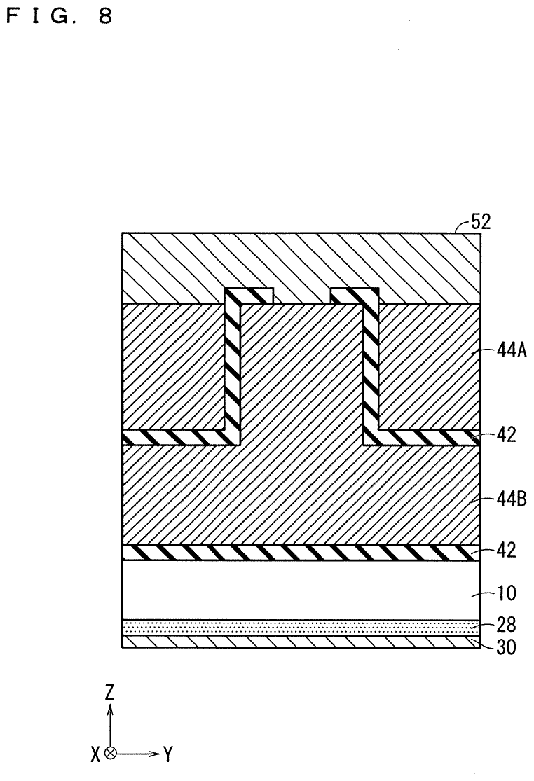

FIG. 8 is a sectional view for illustrating another example of the configuration taken along line D-D in FIG. 6. As exemplified in FIG. 8, both the termination electrode 44A and the termination electrode 44B may be in contact with the channel stopper electrode 52, to make the three electrodes electrically connected to each other. In this case, the termination electrode 44A, the termination electrode 44B, and the channel stopper electrode 52 are at the same potential. Note that the termination electrode 44B may have a plurality of spots in contact with the channel stopper electrodes 52. Alternatively, in FIG. 8, only the termination electrode 44B may be so transformed as to be electrically connected to the channel stopper electrode 52.

### Method of Manufacturing Semiconductor Device

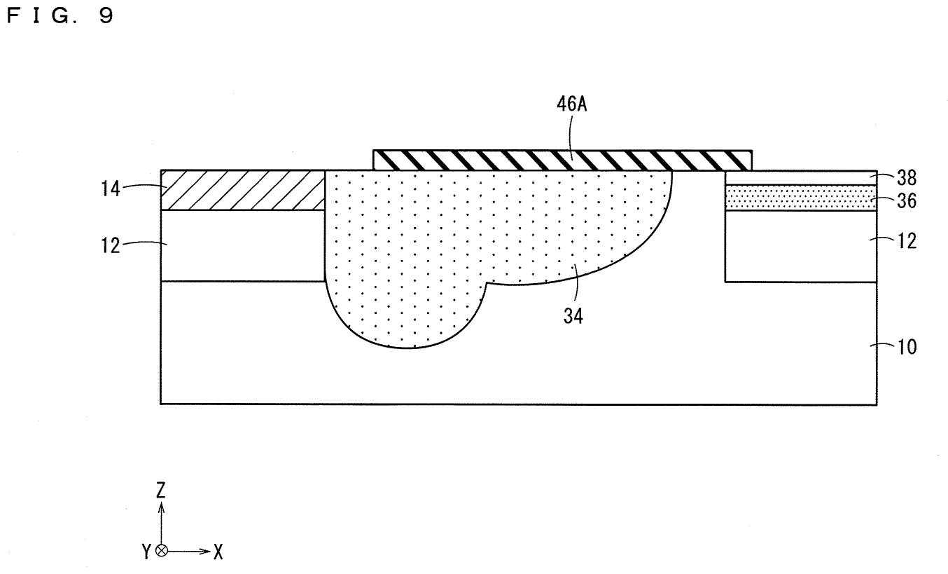

FIGS. 9 to 16 are views for explaining a method of manufacturing a semiconductor device according to the present preferred embodiment.

In a step illustrated in FIG. 9, the n+-type charge accumulation region 12, the p-type channel doped region 14, the p-type impurity region 36, the n+-type channel stopper region 38, and the p+-type impurity region 34 are individually formed on the surface layer of the n-type drift layer 10, and the field insulating film 46A is formed in a part of the upper surface of the n-type drift layer 10 corresponding to the termination region 4, specifically, in a range except the upper surface of the n+-type channel stopper region 38.

The n+-type charge accumulation region 12 and the n+-type channel stopper region 38 are formed by, for example, implantation of impurities such as phosphorus or arsenic into the surface layer of the n-type drift layer 10 using an ion implantation process and subsequent thermal diffusion of the implanted impurities.

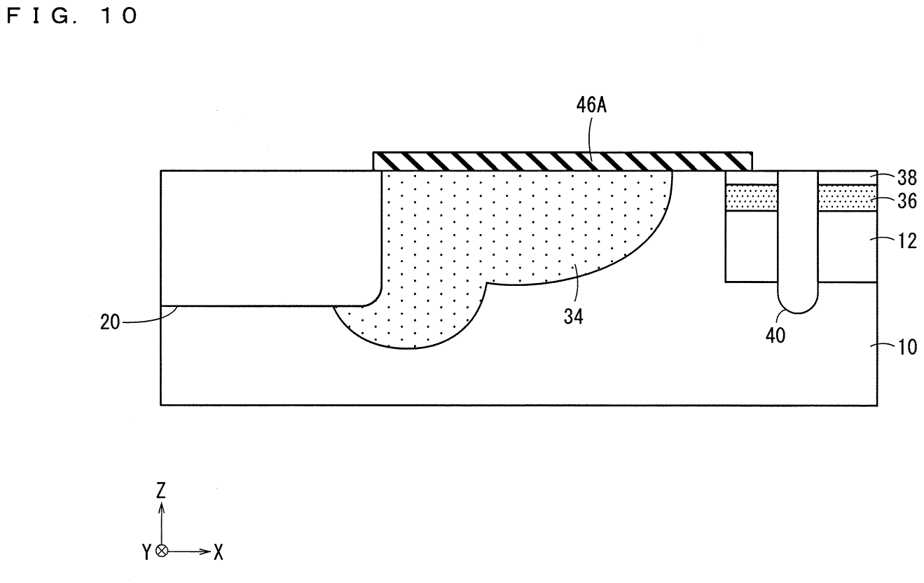

Subsequently, in a step illustrated in FIG. 10, for example, a photolithography process and an anisotropic dry etching process are performed, so that the gate trench 20 is formed at a position adjacent to the n+-type charge accumulation region 12 and the p-type channel doped region 14 in the active region 2, and the termination trench 40 is formed in the upper surface of the n+-type channel stopper region 38 in the termination region 4.

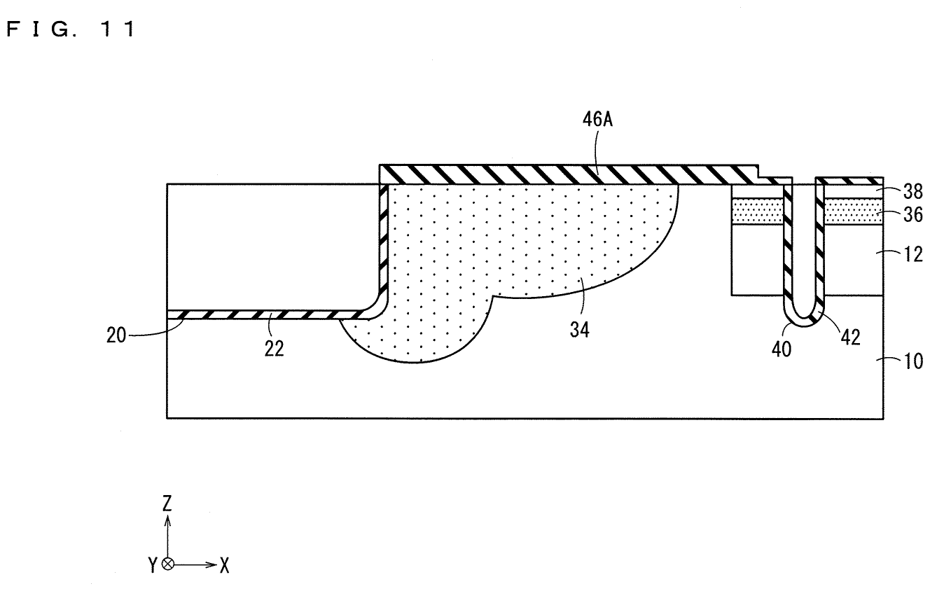

Subsequently, in a step illustrated in FIG. 11, an insulating film is formed on the surface (upper surface and side surface) of the n-type drift layer 10 including the inside of the gate trench 20 and the inside of the termination trench 40. The insulating film is, for example, a silicon oxide film. The insulating film in the gate trench 20 corresponds to the gate insulating film 22. The insulating film in the termination trench 40 corresponds to the termination insulating film 42.

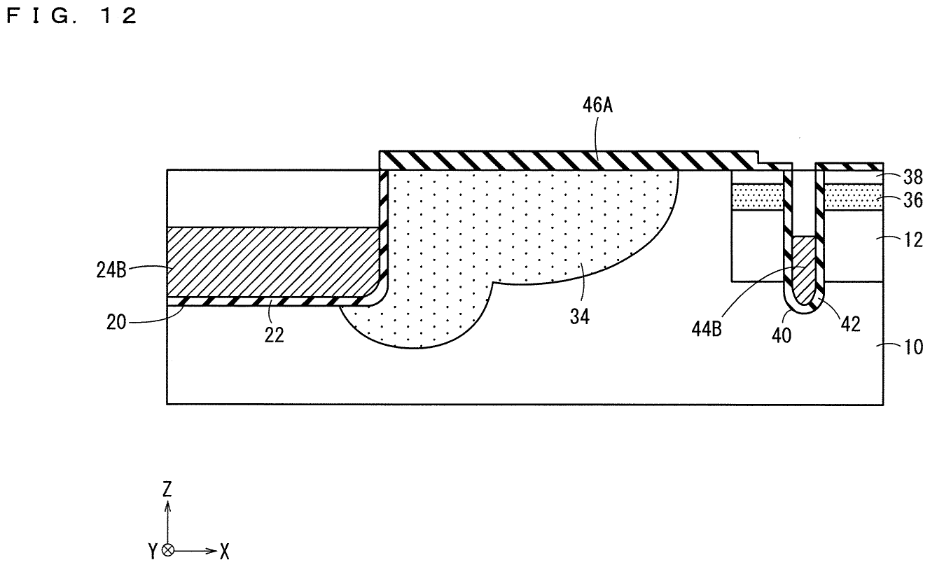

Subsequently, in a step illustrated in FIG. 12, while a formation range is limited using a mask or the like, electrodes are formed in a part of the gate trench 20 and a part of the termination trench 40 by a chemical vapor deposition (that is, CVD) process or the like. The electrodes are, for example, polysilicon. The electrode in the gate trench 20 corresponds to the gate electrode 24B. The electrode in the termination trench 40 corresponds to the termination electrode 44B. In FIG. 12, the electrodes are formed in about a lower half of the gate trench 20 and about a lower half of the termination trench 40, respectively, but, for example, the electrodes may be formed only on sides in the positive X-axis direction in both the trenches or only on sides in the positive Y-axis direction in both the trenches. Alternatively, a combination of an electrode only on a side in the positive X-axis direction in one trench and an electrode in about a lower half of the other trench, or the like may be provided.

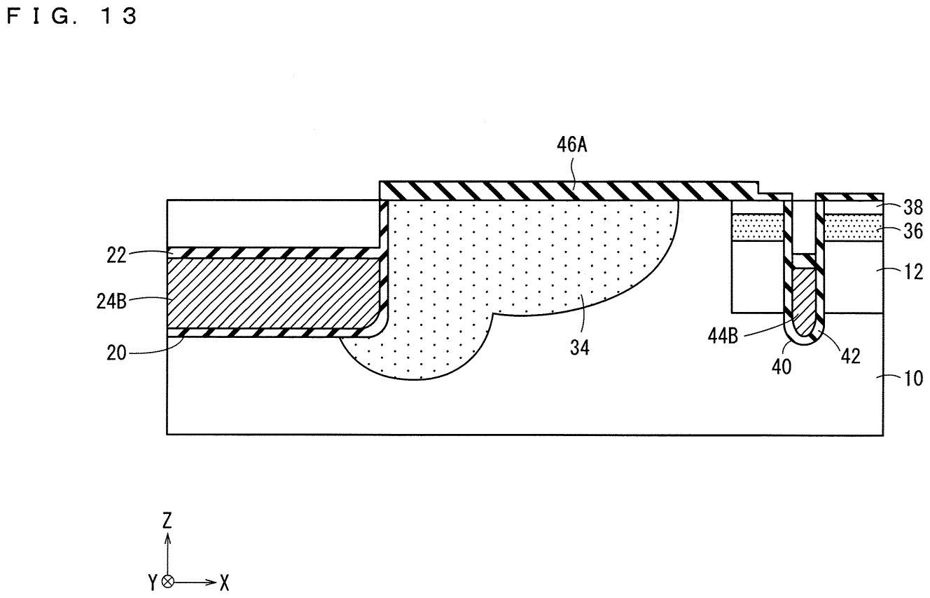

Subsequently, in a step illustrated in FIG. 13, insulating films are formed on the upper surfaces of the gate trench 20 and the termination trench 40. The insulating films are, for example, silicon oxide films. The insulating film in the gate trench 20 corresponds to the gate insulating film 22. The insulating film in the termination trench 40 corresponds to the termination insulating film 42.

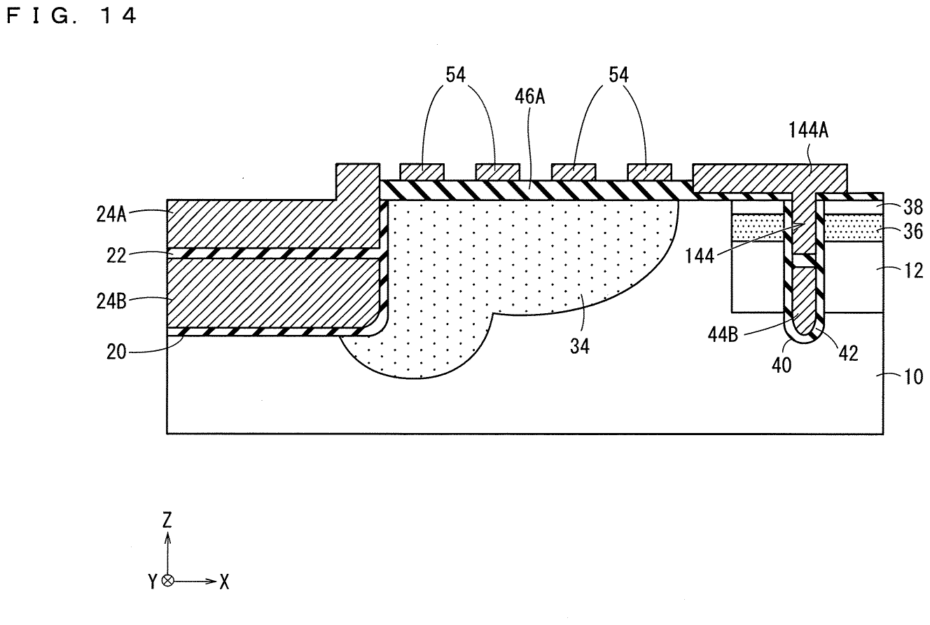

Subsequently, in a step illustrated in FIG. 14, while a formation range is limited using a mask or the like, electrodes are formed in the gate trench 20, on the upper surface of the field insulating film 46A in the termination region 4, and in the termination trench 40 by a CVD process or the like. The electrodes are, for example, polysilicon. The electrode in the gate trench 20 corresponds to the gate electrode 24A. The electrode in the termination trench 40 corresponds to the termination electrode 144. In this regard, the termination electrode 144 includes the connection portion 144A formed so as to extend on the upper surface of the n-type drift layer 10 via an insulating film. The electrode on the upper surface of the field insulating film 46A corresponds to the field plate 54.

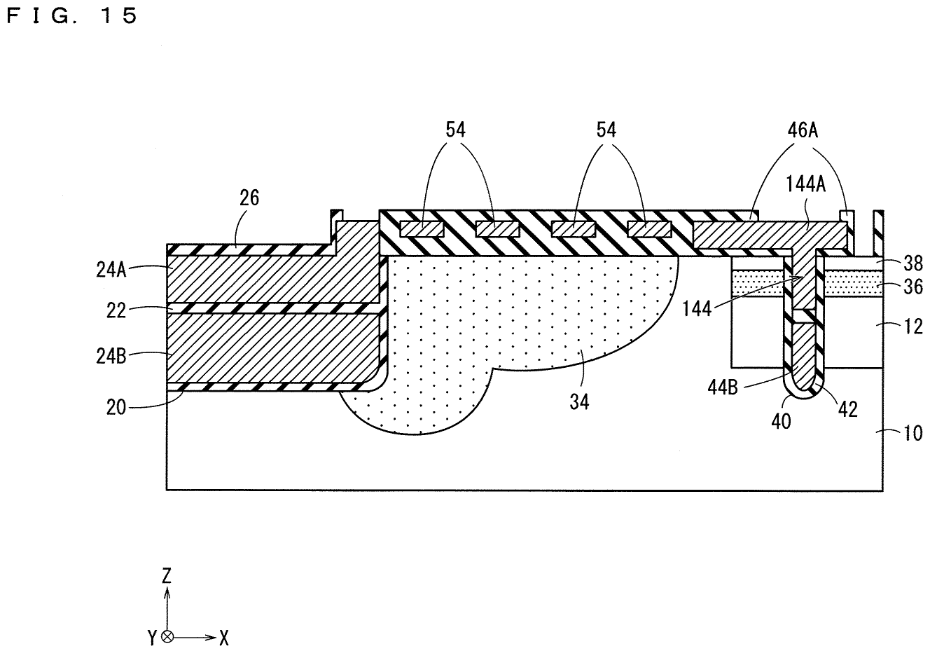

Subsequently, in a step illustrated in FIG. 15, insulating films are formed so as to cover a part of the gate electrode 24A and the field plate 54. The insulating films are, for example, silicon oxide films. The insulating film that is formed so as to expose a part of the gate electrode 24A corresponds to the interlayer insulating film 26. The insulating film covering the field plate 54 is the field insulating film 46A. In this regard, the field insulating film 46A is formed by a process of exposing a part of the n+-type channel stopper region 38.

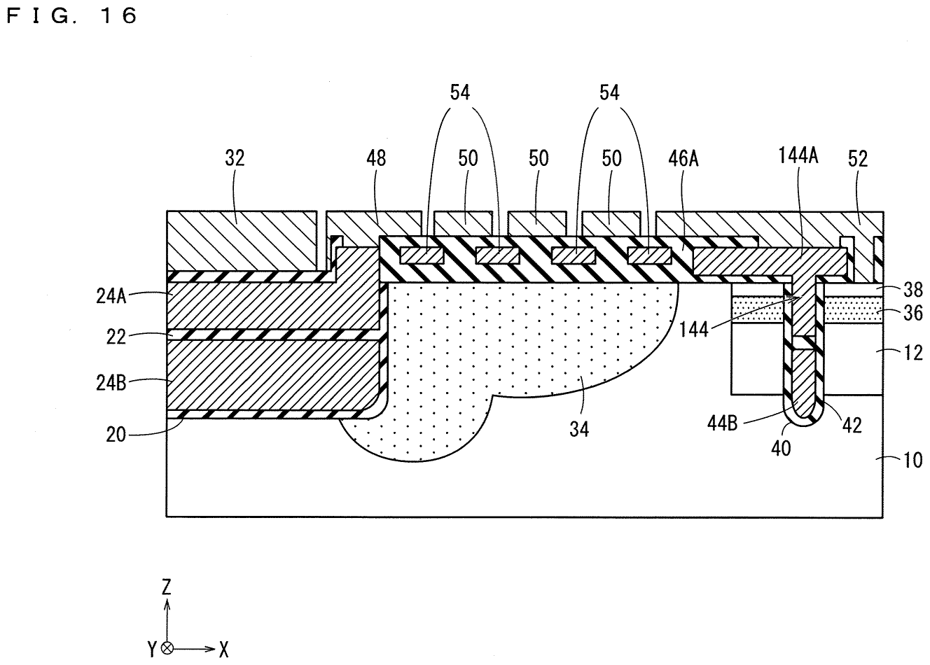

Subsequently, in a step illustrated in FIG. 16, a metal film is formed on the entire surface by a sputtering process and the like, and further, the metal film is patterned by a photolithography process, an anisotropic dry etching process, and the like, so that electrodes are formed. The electrodes are, for example, aluminum. The electrode provided on the upper surface of the gate trench 20 via the interlayer insulating film 26 corresponds to the emitter electrode 32. The electrode provided in contact with the exposed part of the gate electrode 24A corresponds to the gate electrode 48. The electrode provided on the upper surface of the field insulating film 46A so as to be associated with the field plate 54 corresponds to the field plate electrode 50. The electrode provided in contact with the connection portion 144A of the termination electrode 144 and the exposed part of the n+-type channel stopper region 38 corresponds to the channel stopper electrode 52.

In addition to the above-described components, the p+-type collector layer 28 is formed on the lower surface of the n-type drift layer 10, and further, the collector electrode 30 is formed on the lower surface of the p+-type collector layer 28, whereby the semiconductor device illustrated in FIG. 6 is manufactured.

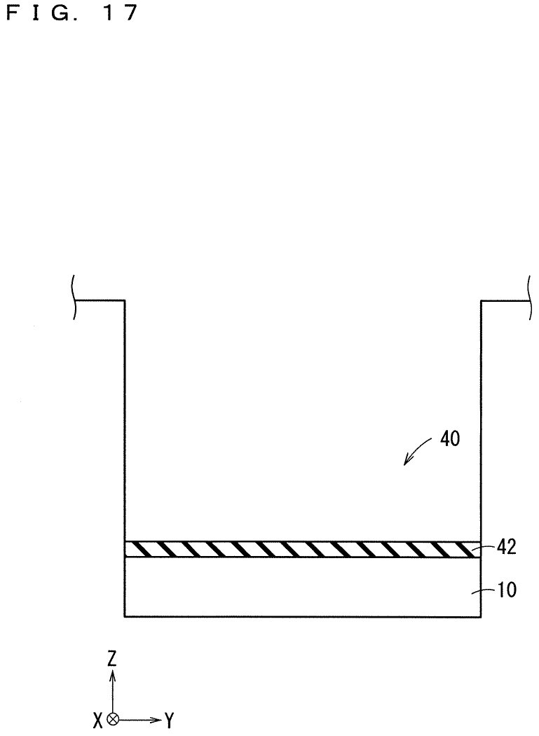

FIGS. 17 to 23 are views for explaining a method of manufacturing the termination electrode in the termination trench illustrated in FIG. 8 in the semiconductor device according to the present preferred embodiment.

In a step illustrated in FIG. 17, the termination trench 40 is formed in the termination region 4 of the n-type drift layer 10, and the termination insulating film 42 is formed in the termination trench 40.

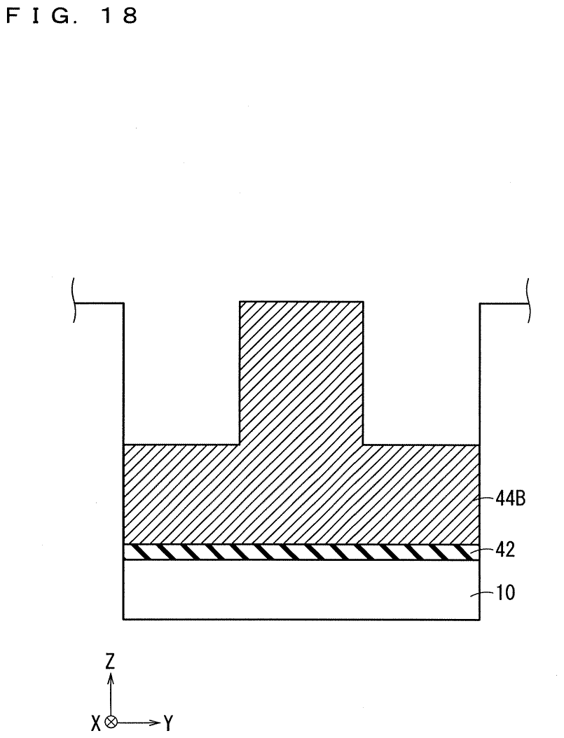

Subsequently, in a step illustrated in FIG. 18, while a formation range is limited using a mask or the like, the termination electrode 44B is formed in a part of the termination trench 40 by a CVD process or the like. For the termination electrode 44B, for example, an electrode is formed a plurality of times while a formation range is changed using different masks, so that the upper surface of the termination electrode 44B has portions of different heights. In FIG. 18, a central portion with respect to the Y-axis direction is formed so as to be higher than end portions with respect to the Y-axis direction, and the higher portion is a portion that comes into contact with the channel stopper electrode 52 even after the termination electrode 144 is formed.

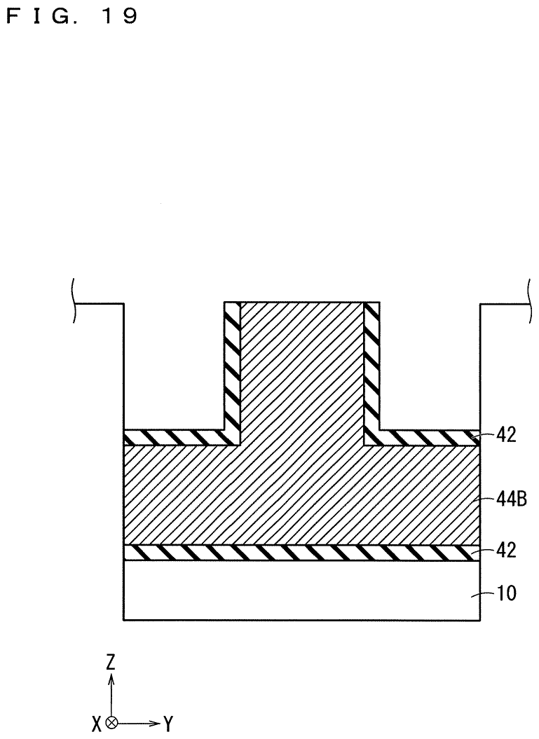

Subsequently, in a step illustrated in FIG. 19, the termination insulating film 42 is formed on the upper surface of the termination trench 40. The termination insulating film 42 is formed on the upper surface of the termination electrode 44B having portions of different heights. The insulating film is, for example, a silicon oxide film.

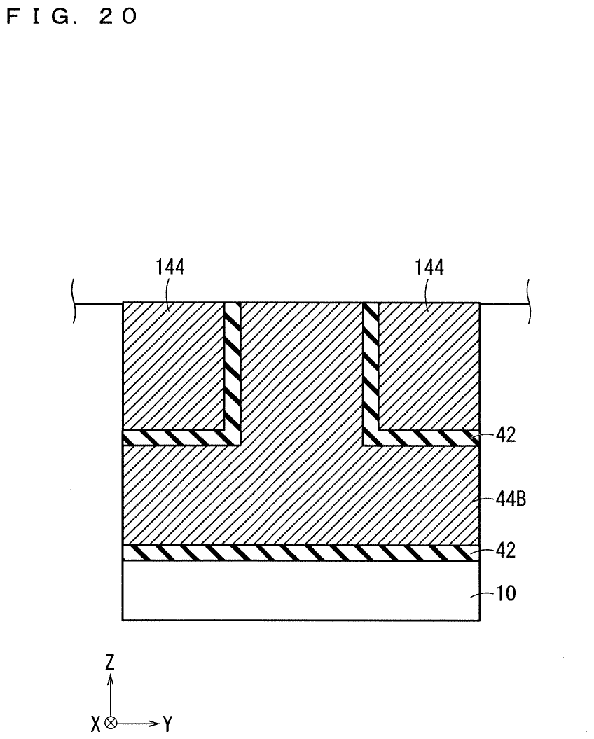

Subsequently, in a step illustrated in FIG. 20, the termination electrode 144 is formed in the termination trench 40 by a CVD process or the like. The termination electrode 144 is formed on portions of a small height, specifically, end portions with respect to the positive and negative Y-axis directions, in the upper surface of the termination electrode 44B.

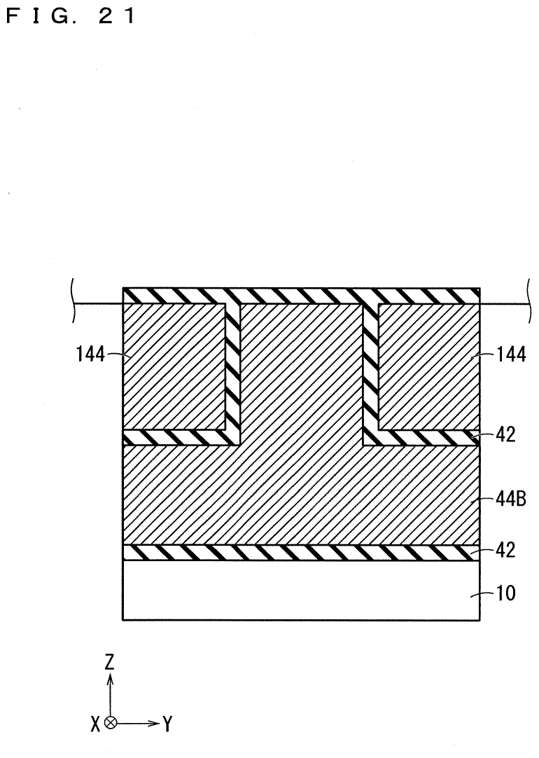

Subsequently, in a step illustrated in FIG. 21, the termination insulating film 42 is formed on the upper surface of the termination trench 40. The termination insulating film 42 is formed on the upper surface of the termination electrode 144 and the exposed upper surface of the termination electrode 44B. The insulating film is, for example, a silicon oxide film.

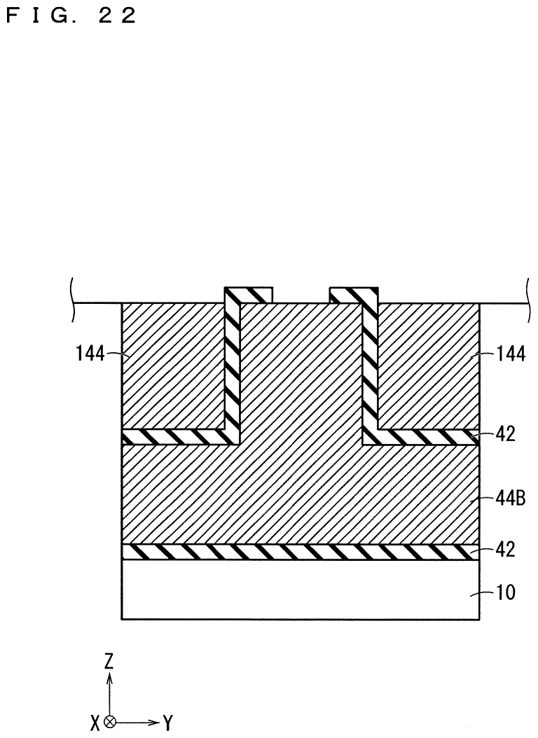

Subsequently, in a step illustrated in FIG. 22, the termination insulating film 42 is patterned, so that a part of the upper surface of the termination electrode 44B and the upper surface of the termination electrode 144 are exposed.

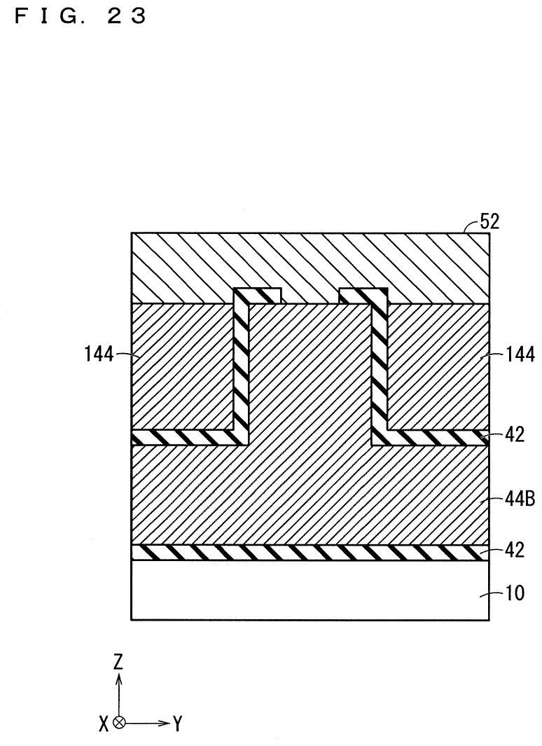

Subsequently, in a step illustrated in FIG. 23, the channel stopper electrode 52 is formed. The channel stopper electrode 52 is, for example, aluminum. The channel stopper electrode 52 is in contact with both the termination electrode 144 and the termination electrode 44B.

### Second Preferred Embodiment

A semiconductor device and a method of manufacturing a semiconductor device according to the present preferred embodiment will be described. Note that, in the following description, components similar to the components described in the above-described preferred embodiment are illustrated with the same reference signs in the drawings, and detailed description thereof will be omitted as appropriate.

### Configuration of Semiconductor Device

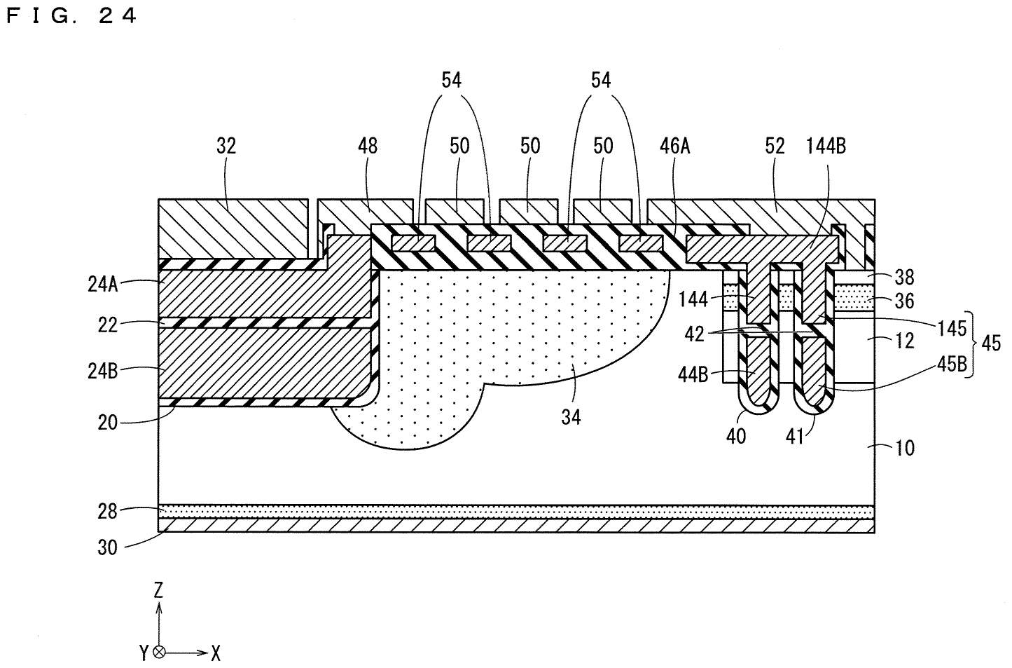

FIG. 24 is a sectional view for illustrating another example of the configuration taken along line A-A in FIG. 1 in the semiconductor device according to the present preferred embodiment. In FIG. 24, along the X-axis direction, a range in which the gate trench 20 is formed corresponds to the active region 2, and a range in the positive X-axis direction with respect to the gate trench 20 corresponds to the termination region 4.

In the example illustrated in FIG. 24, in addition to the components illustrated in FIG. 6, a termination trench 41 formed so as to extend from the upper surface of the n+-type channel stopper region 38 and reach the inside of the n-type drift layer 10, and a termination electrode 45 placed while being surrounded by the termination insulating film 42 in the termination trench 41 are provided.

The termination trench 41 is formed so as to extend along the Y-axis direction. The termination insulating film 42 is formed on an inner wall and a bottom surface of the termination trench 41, and is formed so as to surround the termination electrode 45 in the termination trench 41.

A plurality of termination electrodes 45 are provided in a single termination trench 41. The plurality of termination electrodes 45 are provided apart from each other, and the termination insulating film 42 is interposed between the plurality of termination electrodes 45. In FIG. 24, the termination electrode 45 located on a side in the positive Z-axis direction is referred to as a termination electrode 145, and the termination electrode 45 located on a side in the negative Z-axis direction is referred to as a termination electrode 45B.

Arrangement of the plurality of termination electrodes 45 in the termination trench 41 may be arrangement in which the termination electrodes 45 overlap each other in plan view as illustrated in FIG. 24, in other words, arrangement along the Z-axis direction, or may be arrangement along the Y-axis direction or arrangement along the X-axis direction.

Further, in the example illustrated in FIG. 24, the termination electrode 144 located on a side in the positive Z-axis direction in the termination trench 40 and the termination electrode 145 located on a side in the positive Z-axis direction in the termination trench 41 include, in common with each other, a connection portion 144B that is provided so as to extend on the upper surface of the field insulating film 46A, in other words, extend on the upper surface of the n-type drift layer 10. The channel stopper electrode 52 is in contact with the exposed termination electrode 144 in the termination trench 40 and the exposed termination electrode 145 in the termination trench 41 via the connection portion 144B. Note that the termination electrode 45B, in addition to the termination electrode 145 in the termination trench 41, may also be electrically connected to the channel stopper electrode 52, or only the termination electrode 45B, instead of the termination electrode 145 in the termination trench 41, may be electrically connected to the channel stopper electrode 52.

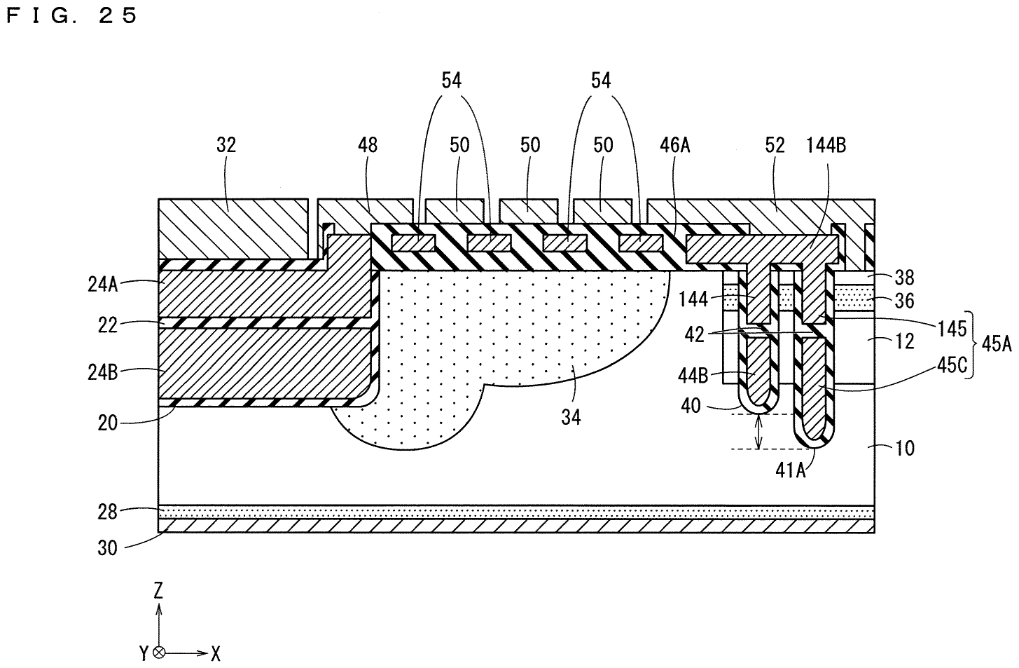

FIG. 25 is a sectional view for illustrating another example of the configuration taken along line A-A in FIG. 1 in the semiconductor device according to the present preferred embodiment. In FIG. 25, along the X-axis direction, a range in which the gate trench 20 is formed corresponds to the active region 2, and a range in the positive X-axis direction with respect to the gate trench 20 corresponds to the termination region 4.

In the example illustrated in FIG. 25, in addition to the components illustrated in FIG. 6, a termination trench 41A formed so as to extend from the upper surface of the n+-type channel stopper region 38 and reach the inside of the n-type drift layer 10, and a termination electrode 45A placed while being surrounded by the termination insulating film 42 in the termination trench 41A are provided.

The termination trench 41A is formed at a position farther from the active region 2 than the termination trench 40. Further, the termination trench 41A is formed so as to have a depth larger than the depth of the termination trench 40. The termination trench 41A is formed so as to extend along the Y-axis direction. The termination insulating film 42 is formed on an inner wall and a bottom surface of the termination trench 41A, and is formed so as to surround the termination electrode 45A in the termination trench 41A.

A plurality of termination electrodes 45A are provided in a single termination trench 41A. The plurality of termination electrodes 45A are provided apart from each other, and the termination insulating film 42 is interposed between the plurality of termination electrodes 45A. In FIG. 25, the termination electrode 45A located on a side in the positive Z-axis direction is referred to as the termination electrode 145, and the termination electrode 45A located on a side in the negative Z-axis direction is referred to as a termination electrode 45C.

Arrangement of the plurality of termination electrodes 45A in the termination trench 41A may be arrangement in which the termination electrodes 45A overlap each other in plan view as illustrated in FIG. 25, in other words, arrangement along the Z-axis direction, or may be arrangement along the Y-axis direction or arrangement along the X-axis direction.

Further, in the example illustrated in FIG. 25, the termination electrode 144 located on a side in the positive Z-axis direction in the termination trench 40 and the termination electrode 145 located on a side in the positive Z-axis direction in the termination trench 41A include, in common with each other, the connection portion 144B that is provided so as to extend on the upper surface of the field insulating film 46A, in other words, extend on the upper surface of the n-type drift layer 10. The channel stopper electrode 52 is in contact with the exposed termination electrode 144 in the termination trench 40 and the exposed termination electrode 145 in the termination trench 41A via the connection portion 144B.

### Third Preferred Embodiment

A semiconductor device and a method of manufacturing a semiconductor device according to the present preferred embodiment will be described. Note that, in the following description, components similar to the components described in the above-described embodiments are illustrated with the same reference signs in the drawings, and detailed description thereof will be omitted as appropriate.

### Configuration of Semiconductor Device

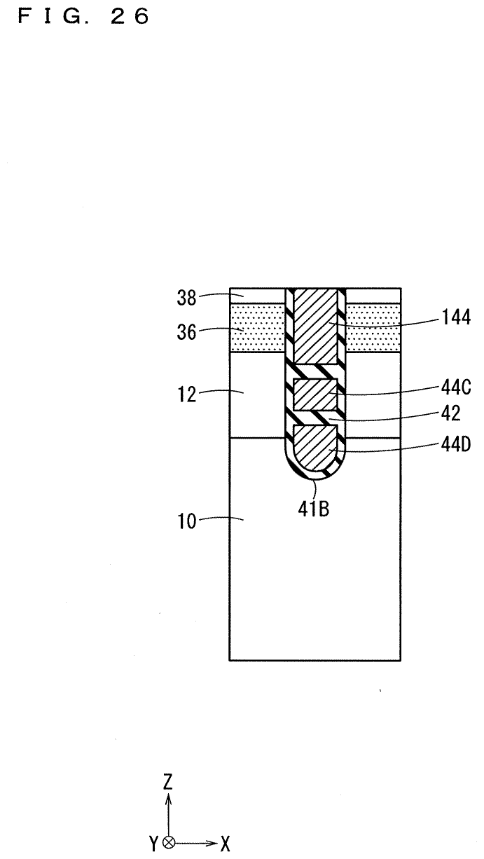

FIG. 26 is a sectional view for illustrating another example of the configuration taken along line D-D in FIG. 6. In FIG. 26, for the sake of convenience, a part of components included in the section taken along line D-D is illustrated.

As exemplified in FIG. 26, a plurality of termination electrodes are provided in a single termination trench 41B. The plurality of termination electrodes are provided apart from each other, and the termination insulating film 42 is interposed between the plurality of termination electrodes. In FIG. 26, the termination electrode located at an endmost position on a side in the positive Z-axis direction is referred to as the termination electrode 144, the termination electrode located at an endmost position on a side in the negative Z-axis direction is referred to as a termination electrode 44D, and the termination electrode located between the termination electrode 144 and the termination electrode 44D is referred to as a termination electrode 44C. Note that, whereas a case where three termination electrodes are formed in a single termination trench is illustrated in FIG. 26, the number of termination electrodes formed in a single termination trench is not limited to that in the case of FIG. 26, and, for example, four or more termination electrodes may be formed.

Arrangement of the plurality of termination electrodes in the termination trench 41B may be arrangement in which the termination electrodes overlap each other in plan view as illustrated in FIG. 26, in other words, arrangement along the Z-axis direction, or may be arrangement along the Y-axis direction, arrangement along the X-axis direction, arrangement in a matrix pattern along a plurality of axis directions, or the like.

All of the plurality of termination electrodes in the termination trench 41B may be in contact with the channel stopper electrode 52, to make the four electrodes electrically connected to each other. In this case, the termination electrode 144, the termination electrode 44C, the termination electrode 44D, and the channel stopper electrode 52 are at the same potential. Meanwhile, at least one termination electrode among the plurality of termination electrodes in the termination trench 41B may be in no contact with the channel stopper electrode 52.

### Fourth Preferred Embodiment

A semiconductor device and a method of manufacturing a semiconductor device according to the present preferred embodiment will be described. Note that, in the following description, components similar to the components described in the above-described preferred embodiments are illustrated with the same reference signs in the drawings, and detailed description thereof will be omitted as appropriate.

### Configuration of Semiconductor Device

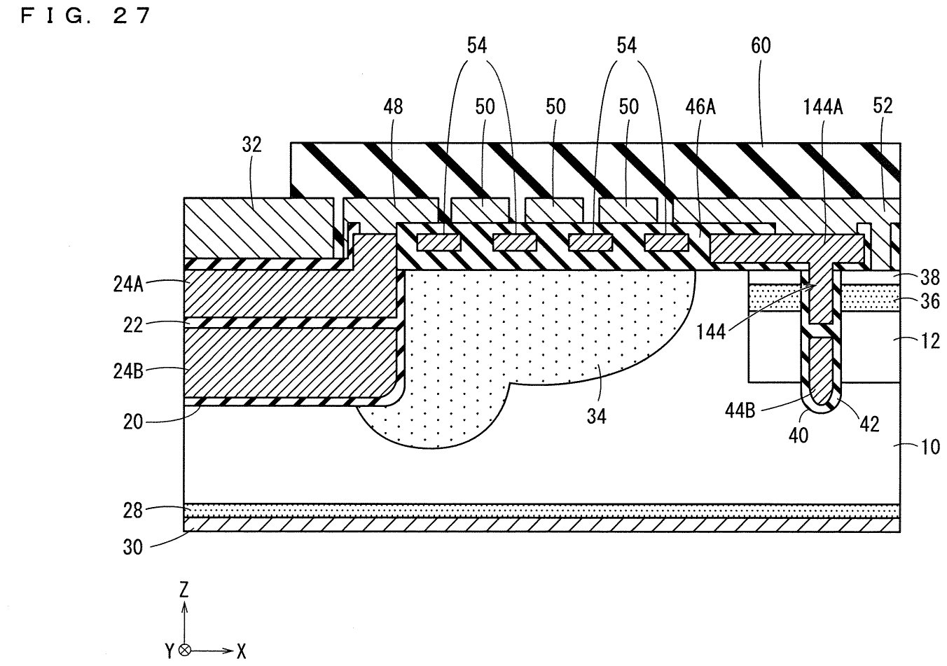

FIG. 27 is a sectional view for illustrating another example of the configuration taken along line A-A in FIG. 1 in the semiconductor device according to the present preferred embodiment. In FIG. 27, along the X-axis direction, a range in which the gate trench 20 is formed corresponds to the active region 2, and a range in the positive X-axis direction with respect to the gate trench 20 corresponds to the termination region 4.

In the example illustrated in FIG. 27, in addition to the components illustrated in FIG. 6, a protective film 60 covering at least the channel stopper electrode 52 is formed. In FIG. 27, the protective film 60 covers a part of the emitter electrode 32, the gate electrode 48, and the field plate electrode 50, in addition to the channel stopper electrode 52. The protective film 60 is made of, for example, a silicon nitride film, a silicon oxide film, polyimide, or the like.

### Fifth Preferred Embodiment

A semiconductor device and a method of manufacturing a semiconductor device according to the present preferred embodiment will be described. Note that, in the following description, components similar to the components described in the above-described preferred embodiments are illustrated with the same reference signs in the drawings, and detailed description thereof will be omitted as appropriate.

### Configuration of Semiconductor Device

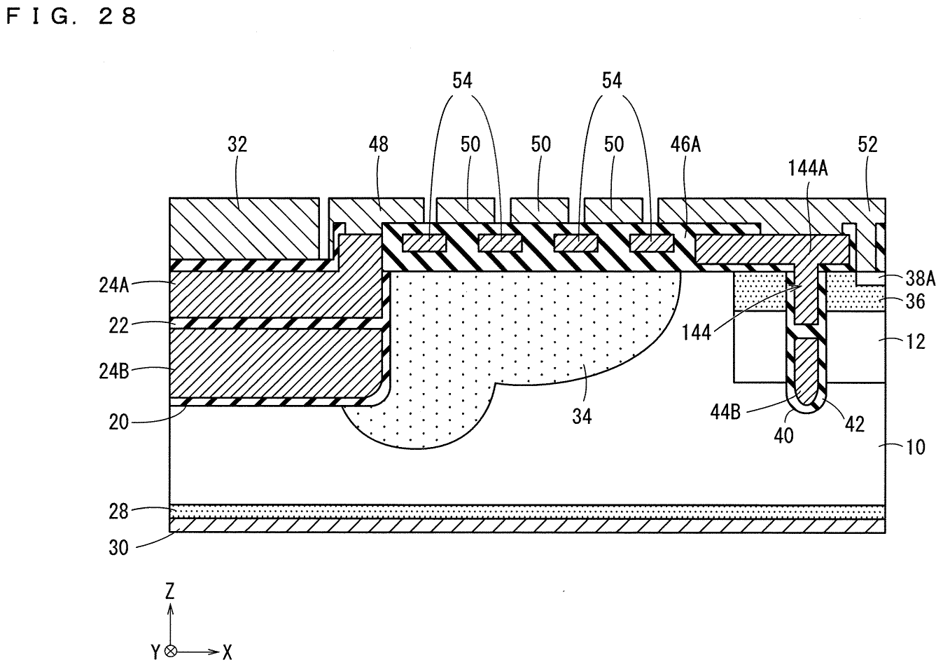

FIG. 28 is a sectional view for illustrating another example of the configuration taken along line A-A in FIG. 1 in the semiconductor device according to the present preferred embodiment. In FIG. 28, along the X-axis direction, a range in which the gate trench 20 is formed corresponds to the active region 2, and a range in the positive X-axis direction with respect to the gate trench 20 corresponds to the termination region 4.

In the example illustrated in FIG. 28, an n+-type channel stopper region 38A is formed instead of the n+-type channel stopper region 38 illustrated in FIG. 6.

In FIG. 28, the termination trench 40 is formed in the n-type drift layer 10 at a position closer to the active region 2 than an end (outer end) of the n+-type channel stopper region 38A on a side opposite to the active region 2. In other words, the outer end of the n+-type channel stopper region 38A is located farther from the active region 2 than the termination trench 40.

In FIG. 28, the n+-type channel stopper region 38A is formed on the surface layer of the n+-type charge accumulation region 12 in the termination region 4, in other words, on the surface layer of the n-type drift layer 10. The n+-type channel stopper region 38A is provided at a position farther from the active region 2 than the connection portion 144A, where the n+-type channel stopper region 38A does not overlap the connection portion 144A in plan view. Note that, in a case where the connection portion 144B extending across the two termination trenches is formed as illustrated in FIGS. 24 and 25, the n+-type channel stopper region 38A is provided at a position farther from the active region 2 than the connection portion 144B, where the n+-type channel stopper region 38A does not overlap the connection portion 144B in plan view.

The n+-type channel stopper region 38A has an impurity concentration higher than the impurity concentration of the n-type drift layer 10. The channel stopper electrode 52 is in contact with the upper surface of the n+-type channel stopper region 38A exposed from the field insulating film 46.

In this regard, a p-type channel stopper region may be provided instead of the n+-type channel stopper region 38A. Note that the p-type channel stopper region is provided at a position similar to the position where the n+-type channel stopper region 38A is provided, and has an impurity concentration higher than that of the n-type drift layer 10.

With the configuration illustrated in FIG. 28, an impurity region where the channel stopper region 38A is to be formed can be activated after the termination electrode is formed in the termination trench and the field plate 54 and the connection portion 144A are further formed as necessary. In other words, it is possible to increase flexibility in timing for forming the channel stopper region 38A by activation. In a case where the channel stopper region 38A is an n-type impurity region, the channel stopper region 38A can be activated simultaneously with, for example, the n+-type source region 16 or the n+-type charge accumulation region 12 in the active region 2. Meanwhile, in a case where the channel stopper region 38A is a p-type impurity region, the channel stopper region 38A can be activated simultaneously with, for example, the p+-type impurity region 18 or the p-type channel doped region 14 in the active region 2.

### Effects Produced by the Plurality of Preferred Embodiments Described Above

Next, examples of effects produced by the plurality of preferred embodiments described above will be described. Note that, in the following description, while effects will be described on the basis of the specific configurations exemplified in the plurality of preferred embodiments described above, the specific configurations may be replaced with other specific configurations exemplified in the present specification as long as similar effects are produced. That is, in the following description, for the sake of convenience, only one of the corresponding specific configurations is described as a representative in some instances, but the specific configuration described as a representative may be replaced with another corresponding specific configuration.

Further, the replacement may be performed among a plurality of preferred embodiments. That is, a combination of respective configurations exemplified in different preferred embodiments may produce similar effects.

According to the preferred embodiments described above, the semiconductor device is a semiconductor device including the active region 2 and the termination region 4 surrounding the active region 2 in plan view. The semiconductor device includes the drift layer 10 of a first conductivity type (n-type), the channel stopper region 38 (or the channel stopper region 38A) of the first conductivity type, a first termination trench, a plurality of termination electrodes, the channel stopper electrode 52, an impurity region of a second conductivity type, the gate trench 20, a plurality of gate electrodes, the interlayer insulating film 26, an upper-surface electrode, and a lower-surface electrode. In this regard, the first termination trench corresponds to, for example, the termination trench 40, the termination trench 41B, or the like. Further, the impurity region of the second conductivity type corresponds to, for example, the p-type channel doped region 14 or the like. Further, the upper-surface electrode corresponds to, for example, the emitter electrode 32 or the like. Further, the lower-surface electrode corresponds to, for example, the collector electrode 30 or the like. The channel stopper region 38 is formed on the surface layer of the drift layer 10 in the termination region 4. Further, the channel stopper region 38 has an impurity concentration higher than that of the drift layer 10. The termination trench 40 is formed in the drift layer 10 in the termination region 4. The plurality of termination electrodes are provided in the termination trench 40 while being surrounded by a first termination insulating film. In this regard, the first termination insulating film corresponds to, for example, the termination insulating film 42 or the like. The channel stopper electrode 52 is electrically connected to the channel stopper region 38 and at least one termination electrode. Further, the channel stopper electrode 52 is provided on the upper surface of the drift layer 10. The p-type channel doped region 14 is formed on the surface layer of the drift layer 10 in the active region 2. The gate trench 20 is formed in the drift layer 10 while being adjacent to the p-type channel doped region 14. The plurality of gate electrodes are provided in the gate trench 20 while being surrounded by the gate insulating film 22. The interlayer insulating film 26 is provided so as to cover the gate trench 20. The emitter electrode 32 is provided so as to cover the upper surface of the drift layer 10 and the interlayer insulating film 26. The collector electrode 30 is provided on the lower surface of the drift layer 10 at least in the active region 2. The plurality of termination electrodes in the termination trench 40 include a first termination electrode and a second termination electrode. In this regard, the first termination electrode corresponds to, for example, the termination electrode 44A, the termination electrode 144, or the like. Further, the second termination electrode corresponds to, for example, the termination electrode 44B, the termination electrode 44D, or the like. The plurality of gate electrodes include a first gate electrode and a second gate electrode. In this regard, the first gate electrode corresponds to, for example, the gate electrode 24A or the like. Further, the second gate electrode corresponds to, for example, the gate electrode 24B or the like. The termination electrode 44A and the termination electrode 44B are provided apart from each other in the termination trench 40. The gate electrode 24A and the gate electrode 24B are provided apart from each other in the gate trench 20.

With this configuration, in which the plurality of termination electrodes are provided in the single termination trench, flexibility in control of a depletion layer can be improved. Further, a channel stopper region can be formed with greater flexibility in position. Moreover, in a case where the plurality of termination electrodes in the termination trench and the plurality of gate electrodes in the gate trench are arranged along the same direction, the termination electrodes and the gate electrodes can be easily manufactured in the same step.

Note that, also in a case where another component exemplified in the present specification is appropriately added to the above-described components, that is, also in a case where another component that is not mentioned as any of the above-described components but is included in the present specification is appropriately added, similar effects can be produced.

Further, according to the preferred embodiments described above, the semiconductor device is a semiconductor device including the active region 2 and the termination region 4 surrounding the active region 2 in plan view. The semiconductor device includes the n-type drift layer 10, the channel stopper region 38A, the termination trench 40, a plurality of termination electrodes, the channel stopper electrode 52, the p-type channel doped region 14, the gate trench 20, a plurality of gate electrodes, the interlayer insulating film 26, the emitter electrode 32, and the collector electrode 30. The channel stopper region 38A is formed on the surface layer of the drift layer 10 in the termination region 4. Further, the channel stopper region 38A has an impurity concentration higher than that of the drift layer 10. The termination trench 40 is formed in the drift layer 10 in the termination region 4. The plurality of termination electrodes are provided in the termination trench 40 while being surrounded by the termination insulating film 42. The channel stopper electrode 52 is electrically connected to the channel stopper region 38A and at least one termination electrode. Further, the channel stopper electrode 52 is provided on the upper surface of the drift layer 10. The p-type channel doped region 14 is formed on the surface layer of the drift layer 10 in the active region 2. The gate trench 20 is formed in the drift layer 10 while being adjacent to the p-type channel doped region 14. The plurality of gate electrodes are provided in the gate trench 20 while being surrounded by the gate insulating film 22. The interlayer insulating film 26 is provided so as to cover the gate trench 20. The emitter electrode 32 is provided so as to cover the upper surface of the drift layer 10 and the interlayer insulating film 26. The collector electrode 30 is provided on the lower surface of the drift layer 10 at least in the active region 2. The termination trench 40 is formed in the drift layer 10 at a position closer to the active region 2 than an outer end of the channel stopper region 38A, that is, an end on a side opposite to the active region 2. The plurality of termination electrodes in the termination trench 40 include the termination electrode 144 and the termination electrode 44B. The plurality of gate electrodes include the gate electrode 24A and the gate electrode 24B. The termination electrode 44A and the termination electrode 44B are provided apart from each other in the termination trench 40. The gate electrode 24A and the gate electrode 24B are provided apart from each other in the gate trench 20.

With this configuration, in which the plurality of termination electrodes are provided in the single termination trench, flexibility in control of a depletion layer can be improved. Further, the conductivity type of the channel stopper region is not limited. Moreover, in a case where the plurality of termination electrodes in the termination trench and the plurality of gate electrodes in the gate trench are arranged along the same direction, the termination electrodes and the gate electrodes can be easily manufactured in the same step.

Note that, also in a case where another component exemplified in the present specification is appropriately added to the above-described components, that is, also in a case where another component that is not mentioned as any of the above-described components but is included in the present specification is appropriately added, similar effects can be produced.

Further, according to the preferred embodiments described above, at least a part of the termination electrode 44A is provided so as to overlap the termination electrode 44B in plan view. At least a part of the gate electrode 24A is provided so as to overlap the gate electrode 24B in plan view. With this configuration, the plurality of termination electrodes in the termination trench and the plurality of gate electrodes in the gate trench are arranged so as to overlap each other in plan view (in other words, they are arranged along the same direction), and thus the termination electrodes and the gate electrodes can be easily manufactured in the same step.

Further, according to the preferred embodiments described above, at least one termination electrode connected to the channel stopper electrode 52 further includes the connection portion 144A (or the connection portion 144B) provided so as to extend on the upper surface of the drift layer 10. With this configuration, the contact area between the channel stopper electrode 52 and the termination electrode 144 is increased, which stabilizes the connection between the two electrodes, thereby improving the reliability of the semiconductor device.

Further, according to the preferred embodiments described above, the channel stopper region 38A is provided at a position farther from the active region 2 than the connection portion 144A (or the connection portion 144B), where the channel stopper region 38A does not overlap the connection portion 144A (or the connection portion 144B) in plan view. With this configuration, an impurity region where the channel stopper region 38A is to be formed can be activated after the termination electrode is formed in the termination trench and the field plate 54 and the connection portion 144A (or the connection portion 144B) are further formed as necessary. In other words, it is possible to increase flexibility in timing for forming the channel stopper region 38A by activation.

Further, according to the preferred embodiments described above, both the termination electrode 44A and the termination electrode 44B are electrically connected to the channel stopper electrode 52. With this configuration, the plurality of termination electrodes placed in the single termination trench are at the same potential and thus are stabilized, which enables an increase in accuracy in control of a depletion layer.

Further, according to the preferred embodiments described above, the termination electrode 44B is not electrically connected to the channel stopper electrode 52. With this configuration, it is possible to increase flexibility in control of a depletion layer by using the termination electrode 44B as a floating electrode. Further, there is no need to form a contact portion for bringing the termination electrode 44B and the channel stopper electrode 52 into contact with each other, which eliminates a need to change the formation range using different masks in forming the termination electrode 44B, resulting in reduction of the number of masks and the number of steps.

Further, according to the preferred embodiments described above, the semiconductor device includes a second termination trench formed in the drift layer 10 in the termination region 4. In this regard, the second termination trench corresponds to, for example, the termination trench 41, the termination trench 41A, or the like. The plurality of termination electrodes are also provided in the termination trench 41 while being surrounded by a second termination insulating film. In this regard, the second termination insulating film corresponds to, for example, the termination insulating film 42 or the like. The channel stopper electrode 52 is provided on the upper surface of the drift layer 10 while being electrically connected to the channel stopper region 38, at least one termination electrode in the termination trench 40, and at least one termination electrode in the termination trench 41. The plurality of termination electrodes in the termination trench 41 include a third termination electrode and a fourth termination electrode. In this regard, the third termination electrode corresponds to, for example, the termination electrode 145 or the like. Meanwhile, the fourth termination electrode corresponds to, for example, the termination electrode 45B, the termination electrode 45C, or the like. The termination electrode 145 and the termination electrode 45B are provided apart from each other in the termination trench 41. With this configuration, in which the plurality of termination electrodes are provided in each of the plurality of termination trenches, flexibility in control of a depletion layer can be increased.

Further, according to the preferred embodiments described above, at least a part of the termination electrode 145 is provided so as to overlap the termination electrode 45B in plan view. With this configuration, in which the plurality of termination electrodes in each of the plurality of the termination trenches and the plurality of gate electrodes in the gate trench are arranged so as to overlap each other in plan view (in other words, arranged along the same direction), the termination electrodes and the gate electrodes can be easily manufactured in the same step.

Further, according to the preferred embodiments described above, the termination trench 41 is formed at a position farther from the active region 2 than the termination trench 40. Moreover, the termination trench 41 is formed deeper than the termination trench 40. This configuration makes it easy to place the termination electrodes along an outer edge of a depletion layer extending from the upper surface of the n-type drift layer 10, from the active region 2 toward the termination region 4. Hence, extension of the depletion layer can be effectively suppressed.

Further, according to the preferred embodiments described above, the plurality of termination electrodes in the termination trench 41B further include a fifth termination electrode. In this regard, the fifth termination electrode corresponds to, for example, the termination electrode 44C or the like. The termination electrode 44C is provided apart from the termination electrode 144 and the termination electrode 44D in the termination trench 41B. With this configuration, in which the three termination electrodes are provided in the single termination trench, flexibility in control of a depletion layer can be increased.

Further, according to the preferred embodiments described above, the semiconductor device includes the protective film 60 provided so as to cover the channel stopper electrode 52. With this configuration, in which the channel stopper electrode 52 is covered with the protective film 60, the breakdown voltage and reliability of the semiconductor device can be improved.

Further, according to the preferred embodiments described above, the semiconductor device includes the n+-type charge accumulation region 12 provided below the channel stopper region 38 while being adjacent to the termination trench 40. The charge accumulation region 12 has an impurity concentration higher than that of the drift layer 10 and lower than that of the channel stopper region 38. With this configuration, a depletion layer can be effectively suppressed.

According to the preferred embodiments described above, in the method of manufacturing a semiconductor device, the p-type channel doped region 14 is formed on the surface layer of the n-type drift layer 10 in the active region 2. Then, the channel stopper region 38 of the first conductivity type having an impurity concentration higher than that of the drift layer 10 is formed on the surface layer of the drift layer 10 in the termination region 4. Then, the gate trench 20 is formed in the drift layer 10 at a position adjacent to the p-type channel doped region 14 in the active region 2, and the termination trench 40 is formed in the drift layer 10 in the termination region 4. Then, the gate insulating film 22 and the termination insulating film 42 are formed in the gate trench 20 and the termination trench 40, respectively. Then, a plurality of gate electrodes surrounded by the gate insulating film 22 and a plurality of termination electrodes surrounded by the termination insulating film 42 are formed in the gate trench 20 and the termination trench 40, respectively. Then, the interlayer insulating film 26 covering the gate trench 20 is formed. Then, the channel stopper electrode 52 electrically connected to the channel stopper region 38 and at least one termination electrode is formed on the upper surface of the drift layer 10. Then, the emitter electrode 32 covering the upper surface of the drift layer 10 and the interlayer insulating film 26 is formed. Then, the collector electrode 30 is formed on the lower surface of the drift layer 10 at least in the active region 2. In this regard, the plurality of termination electrodes include the termination electrode 44A and the termination electrode 44B. Further, the plurality of gate electrodes include the gate electrode 24A and the gate electrode 24B. Further, the termination electrode 44A and the termination electrode 44B are provided apart from each other in the termination trench 40. Further, the gate electrode 24A and the gate electrode 24B are provided apart from each other in the gate trench 20.

With this configuration, in which the plurality of termination electrodes are provided in the single termination trench, flexibility in control of a depletion layer can be improved. Further, a channel stopper region can be formed with greater flexibility in position. Moreover, in a case where the plurality of termination electrodes in the termination trench and the plurality of gate electrodes in the gate trench are arranged along the same direction, the termination electrodes and the gate electrodes can be easily manufactured in the same step.

Note that the order in which the respective processes are performed can be changed unless otherwise specified.

Further, also in a case where another component exemplified in the present specification is appropriately added to the above-described components, that is, also in a case where another component that is not mentioned as any of the above-described components but is included in the present specification is appropriately added, similar effects can be produced.

Further, according to the preferred embodiments described above, in the method of manufacturing a semiconductor device, the p-type channel doped region 14 is formed on the surface layer of the n-type drift layer 10 in the active region 2. Then, the channel stopper region 38A having an impurity concentration higher than that of the drift layer 10 is formed on the surface layer of the drift layer 10 in the termination region 4. Then, the gate trench 20 is formed in the drift layer 10 at a position adjacent to the p-type channel doped region 14 in the active region 2, and the termination trench 40 is formed in the drift layer 10 in the termination region 4. Then, the gate insulating film 22 and the termination insulating film 42 are formed in the gate trench 20 and the termination trench 40, respectively. Then, a plurality of gate electrodes surrounded by the gate insulating film 22 and a plurality of termination electrodes surrounded by the termination insulating film 42 are formed in the gate trench 20 and the termination trench 40, respectively. Then, the interlayer insulating film 26 covering the gate trench 20 is formed. Then, the channel stopper electrode 52 electrically connected to the channel stopper region 38A and at least one termination electrode is formed on the upper surface of the drift layer 10. Then, the emitter electrode 32 covering the upper surface of the drift layer 10 and the interlayer insulating film 26 is formed. Then, the collector electrode 30 is formed on the lower surface of the drift layer 10 at least in the active region 2. In this regard, the termination trench 40 is formed in the drift layer 10 at a position closer to the active region 2 than an outer end of the channel stopper region 38A, that is, an end on a side opposite to the active region 2. Further, the plurality of termination electrodes include the termination electrode 44A and the termination electrode 44B. Further, the plurality of gate electrodes include the gate electrode 24A and the gate electrode 24B. Further, the termination electrode 44A and the termination electrode 44B are provided apart from each other in the termination trench 40. Further, the gate electrode 24A and the gate electrode 24B are provided apart from each other in the gate trench 20.

With this configuration, in which the plurality of termination electrodes are provided in the single termination trench, flexibility in control of a depletion layer can be improved. Further, the conductivity type of the channel stopper region is not limited. Moreover, in a case where the plurality of termination electrodes in the termination trench and the plurality of gate electrodes in the gate trench are arranged along the same direction, the termination electrodes and the gate electrodes can be easily manufactured in the same step.

Note that the order in which the respective processes are performed can be changed unless otherwise specified.

Further, also in a case where another component exemplified in the present specification is appropriately added to the above-described components, that is, also in a case where another component that is not mentioned as any of the above-described components but is included in the present specification is appropriately added, similar effects can be produced.

Further, according to the preferred embodiment described above, forming the plurality of termination electrodes includes forming at least one termination electrode connected to the channel stopper electrode 52 so as to include the connection portion 144A (or the connection portion 144B) provided so as to extend on the upper surface of the drift layer 10, and forming the channel stopper region 38A includes forming the channel stopper region 38A at a position farther from the active region 2 than the connection portion 144A (or the connection portion 144B), where the channel stopper region 38A does not overlap the connection portion in plan view. Then, after the plurality of termination electrodes are formed, regions of the same conductivity type in the active region 2 and the channel stopper region 38A are simultaneously activated. With this configuration, an impurity region where the channel stopper region 38A is to be formed can be activated after the termination electrode is formed in the termination trench and the field plate 54 and the connection portion 144A (or the connection portion 144B) are further formed as necessary. In other words, it is possible to increase flexibility in timing for forming the channel stopper region 38A by activation. In a case where the channel stopper region 38A is an n-type impurity region, the channel stopper region 38A can be activated simultaneously with, for example, the n+-type source region 16 or the n+-type charge accumulation region 12 in the active region 2. Meanwhile, in a case where the channel stopper region 38A is a p-type impurity region, the channel stopper region 38A can be activated simultaneously with, for example, the p+-type impurity region 18 or the p-type channel doped region 14 in the active region 2.

### Modifications of Preferred Embodiments Described Above

In the preferred embodiments described above, properties, materials, dimensions, shapes, relative positional relationships, conditions for implementation, and the like of the respective components are described in some instances, but these are mere examples in all aspects and are not restrictive.

Hence, innumerable modifications and equivalents, examples of which have not been described, are conceivable within the scope of the technology disclosed in the present specification. For example, there are included a case where at least one component is modified, added, or omitted, and a case where at least one component in at least one preferred embodiment is extracted and combined with a component in another embodiment.

Further, in at least one preferred embodiment described above, in a case where a material name or the like is described without specific notes, it is assumed that the material includes other additives such as an alloy, for example, unless contradiction occurs.

Further, in a case where it is described in the above-described preferred embodiments that “one” component is provided, it means that “one or more” components may be provided, unless contradiction occurs.

Further, each component in the preferred embodiments described above is a conceptual unit, and the scope of the technology disclosed in the present specification includes a case where one component includes a plurality of structures, a case where one component corresponds to a part of a certain structure, and a case where a plurality of components are included in one structure.

Further, each component in the preferred embodiments described above includes a structure having another configuration or shape as long as the same function is performed.

Further, the description in the present specification is referred to for all purposes related to the present technology, and nothing therein is recognized as prior art.

Further, in the preferred embodiments described above, the semiconductor substrate is of an n-type, but may be of a p-type. Moreover, in the preferred embodiments described above, the IGBT has been described as an example of the semiconductor device, but a case where an example of the semiconductor device is a metal-oxide-semiconductor field-effect transistor (that is, MOSFET) is also conceivable.

Note that, in a case where an example of the semiconductor device is a MOSFET, an emitter electrode corresponds to a source electrode, and a collector electrode corresponds to a drain electrode.

Further, in the preferred embodiments described above, it has been described that the first conductivity type is an n-type and the second conductivity type is a p-type, but they may be reversed, that is, the first conductivity type may be a p-type and the second conductivity type may be an n-type.

Hereinafter, various aspects of the present disclosure will be collectively described as appendices.

### Appendix 1

A semiconductor device including an active region and a termination region surrounding the active region in plan view, comprising:
a drift layer of a first conductivity type;
a channel stopper region of the first conductivity type that is formed on a surface layer of the drift layer in the termination region and has an impurity concentration higher than that of the drift layer;
a first termination trench formed in the drift layer in the termination region;
a plurality of termination electrodes provided while being surrounded by a first termination insulating film in the first termination trench;
a channel stopper electrode provided on an upper surface of the drift layer while being electrically connected to the channel stopper region and at least one of the termination electrodes;
an impurity region of a second conductivity type formed on the surface layer of the drift layer in the active region;
a gate trench formed in the drift layer while being adjacent to the impurity region;
a plurality of gate electrodes provided while being surrounded by a gate insulating film in the gate trench;
an interlayer insulating film provided so as to cover the gate trench;
an upper-surface electrode provided so as to cover the upper surface of the drift layer and the interlayer insulating film; and
a lower-surface electrode provided on a lower surface of the drift layer at least in the active region,
wherein
the plurality of termination electrodes in the first termination trench include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

### Appendix 2

A semiconductor device including an active region and a termination region surrounding the active region in plan view, comprising:
a drift layer of a first conductivity type;
a channel stopper region that is formed on a surface layer of the drift layer in the termination region and has an impurity concentration higher than that of the drift layer;
a first termination trench formed in the drift layer in the termination region;
a plurality of termination electrodes provided while being surrounded by a first termination insulating film in the first termination trench;
a channel stopper electrode provided on an upper surface of the drift layer while being electrically connected to the channel stopper region and at least one of the termination electrodes;
an impurity region of a second conductivity type formed on the surface layer of the drift layer in the active region;
a gate trench formed in the drift layer while being adjacent to the impurity region;
a plurality of gate electrodes provided while being surrounded by a gate insulating film in the gate trench;
an interlayer insulating film provided so as to cover the gate trench;
an upper-surface electrode provided so as to cover the upper surface of the drift layer and the interlayer insulating film; and
a lower-surface electrode formed on a lower surface of the drift layer at least in the active region,
wherein
the first termination trench is formed in the drift layer at a position closer to the active region than an outer end of the channel stopper region, the outer end being an end on a side opposite to the active region,
the plurality of termination electrodes in the first termination trench include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

### Appendix 3

The semiconductor device according to appendix 1 or 2, wherein
at least a part of the first termination electrode is provided so as to overlap the second termination electrode in plan view, and
at least a part of the first gate electrode is provided so as to overlap the second gate electrode in plan view.

### Appendix 4

The semiconductor device according to any one of appendices 1 to 3, wherein the at least one termination electrode connected to the channel stopper electrode further includes a connection portion provided so as to extend on the upper surface of the drift layer.

### Appendix 5

The semiconductor device according to appendix 4, wherein the channel stopper region is provided at a position farther from the active region than the connection portion, where the channel stopper region does not overlap the connection portion in plan view.

### Appendix 6

The semiconductor device according to any one of appendices 1 to 5, wherein both the first termination electrode and the second termination electrode are electrically connected to the channel stopper electrode.

### Appendix 7

The semiconductor device according to any one of appendices 1 to 5, wherein the second termination electrode is not electrically connected to the channel stopper electrode.

### Appendix 8

The semiconductor device according to any one of appendices 1 to 7, further comprising a second termination trench formed in the drift layer in the termination region,
wherein
the plurality of termination electrodes are also provided in the second termination trench while being surrounded by a second termination insulating film,
the channel stopper electrode is provided on the upper surface of the drift layer while being electrically connected to the channel stopper region, at least one of the termination electrodes in the first termination trench, and at least one of the termination electrodes in the second termination trench,
the plurality of termination electrodes in the second termination trench include a third termination electrode and a fourth termination electrode, and
the third termination electrode and the fourth termination electrode are provided apart from each other in the second termination trench.

### Appendix 9

The semiconductor device according to appendix 8, wherein at least a part of the third termination electrode is provided so as to overlap the fourth termination electrode in plan view.

### Appendix 10

The semiconductor device according to appendix 8 or 9, wherein the second termination trench is formed at a position farther from the active region than the first termination trench, and
the second termination trench is formed deeper than the first termination trench.

### Appendix 11

The semiconductor device according to any one of appendices 1 to 10, wherein
the plurality of termination electrodes in the first termination trench further include a fifth termination electrode, and
the fifth termination electrode is provided apart from the first termination electrode and the second termination electrode in the first termination trench.

### Appendix 12

The semiconductor device according to any one of appendices 1 to 11, further comprising a protective film provided so as to cover the channel stopper electrode.

### Appendix 13

The semiconductor device according to any one of appendices 1 to 12, further comprising a charge accumulation region of the first conductivity type provided below the channel stopper region while being adjacent to the first termination trench,
wherein the charge accumulation region has an impurity concentration higher than that of the drift layer and lower than that of the channel stopper region.

### Appendix 14

A method of manufacturing a semiconductor device including an active region and a termination region surrounding the active region in plan view, comprising:
forming an impurity region of a second conductivity type on a surface layer of a drift layer of a first conductivity type in the active region;
forming a channel stopper region of the first conductivity type having an impurity concentration higher than that of the drift layer, on the surface layer of the drift layer in the termination region;
forming a gate trench in the drift layer at a position adjacent to the impurity region in the active region and forming a first termination trench in the drift layer in the termination region;
forming a gate insulating film and a first termination insulating film in the gate trench and the first termination trench, respectively;
forming a plurality of gate electrodes surrounded by the gate insulating film and a plurality of termination electrodes surrounded by the first termination insulating film in the gate trench and the first termination trench, respectively;
forming an interlayer insulating film covering the gate trench;
forming a channel stopper electrode electrically connected to the channel stopper region and at least one of the termination electrodes, on an upper surface of the drift layer;
forming an upper-surface electrode covering the upper surface of the drift layer and the interlayer insulating film; and
forming a lower-surface electrode on a lower surface of the drift layer at least in the active region,
wherein
the plurality of termination electrodes include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

### Appendix 15

A method of manufacturing a semiconductor device including an active region and a termination region surrounding the active region in plan view, comprising:
forming an impurity region of a second conductivity type on a surface layer of a drift layer of a first conductivity type in the active region;
forming a channel stopper region having an impurity concentration higher than that of the drift layer, on the surface layer of the drift layer in the termination region;
forming a gate trench in the drift layer at a position adjacent to the impurity region in the active region and forming a first termination trench in the drift layer in the termination region;
forming a gate insulating film and a first termination insulating film in the gate trench and the first termination trench, respectively;
forming a plurality of gate electrodes surrounded by the gate insulating film and a plurality of termination electrodes surrounded by the first termination insulating film in the gate trench and the first termination trench, respectively;
forming an interlayer insulating film covering the gate trench;
forming a channel stopper electrode electrically connected to the channel stopper region and at least one of the termination electrodes, on an upper surface of the drift layer;
forming an upper-surface electrode covering the upper surface of the drift layer and the interlayer insulating film; and
forming a lower-surface electrode on a lower surface of the drift layer at least in the active region,
wherein
the first termination trench is formed in the drift layer at a position closer to the active region than an outer end of the channel stopper region, the outer end being an end on a side opposite to the active region,
the plurality of termination electrodes include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

### Appendix 16

The method of manufacturing a semiconductor device according to appendix 15, wherein
forming the plurality of termination electrodes includes forming the at least one termination electrode connected to the channel stopper electrode so as to include a connection portion provided so as to extend on the upper surface of the drift layer,
forming the channel stopper region includes forming the channel stopper region at a position farther from the active region than the connection portion, where the channel stopper region does not overlap the connection portion in plan view, and
regions of the same conductivity type in the active region and the channel stopper region are simultaneously activated after the plurality of termination electrodes are formed.

While the disclosure has been shown and described in detail, the foregoing description is in all aspects illustrative and not restrictive. It is therefore understood that numerous modifications and variations can be devised.

What is claimed is:

1. A semiconductor device including an active region and a termination region surrounding the active region in plan view, comprising:
a drift layer of a first conductivity type;
a channel stopper region of the first conductivity type that is formed on a surface layer of the drift layer in the termination region and has an impurity concentration higher than that of the drift layer;
a first termination trench formed in the drift layer in the termination region;
a plurality of termination electrodes provided while being surrounded by a first termination insulating film in the first termination trench;
a channel stopper electrode provided on an upper surface of the drift layer while being electrically connected to the channel stopper region and at least one of the termination electrodes;
an impurity region of a second conductivity type formed on the surface layer of the drift layer in the active region;
a gate trench formed in the drift layer while being adjacent to the impurity region;
a plurality of gate electrodes provided while being surrounded by a gate insulating film in the gate trench;
an interlayer insulating film provided so as to cover the gate trench;
an upper-surface electrode provided so as to cover the upper surface of the drift layer and the interlayer insulating film; and
a lower-surface electrode provided on a lower surface of the drift layer at least in the active region,
wherein
the plurality of termination electrodes in the first termination trench include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

2. A semiconductor device including an active region and a termination region surrounding the active region in plan view, comprising:
a drift layer of a first conductivity type;
a channel stopper region that is formed on a surface layer of the drift layer in the termination region and has an impurity concentration higher than that of the drift layer;
a first termination trench formed in the drift layer in the termination region;
a plurality of termination electrodes provided while being surrounded by a first termination insulating film in the first termination trench;
a channel stopper electrode provided on an upper surface of the drift layer while being electrically connected to the channel stopper region and at least one of the termination electrodes;
an impurity region of a second conductivity type formed on the surface layer of the drift layer in the active region;
a gate trench formed in the drift layer while being adjacent to the impurity region;
a plurality of gate electrodes provided while being surrounded by a gate insulating film in the gate trench;
an interlayer insulating film provided so as to cover the gate trench;
an upper-surface electrode provided so as to cover the upper surface of the drift layer and the interlayer insulating film; and
a lower-surface electrode formed on a lower surface of the drift layer at least in the active region,
wherein
the first termination trench is formed in the drift layer at a position closer to the active region than an outer end of the channel stopper region, the outer end being an end on a side opposite to the active region,
the plurality of termination electrodes in the first termination trench include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

3. The semiconductor device according to claim 1, wherein
at least a part of the first termination electrode is provided so as to overlap the second termination electrode in plan view, and
at least a part of the first gate electrode is provided so as to overlap the second gate electrode in plan view.

4. The semiconductor device according to claim 1, wherein the at least one termination electrode connected to the channel stopper electrode further includes a connection portion provided so as to extend on the upper surface of the drift layer.

5. The semiconductor device according to claim 4, wherein the channel stopper region is provided at a position farther from the active region than the connection portion, where the channel stopper region does not overlap the connection portion in plan view.

6. The semiconductor device according to claim 1, wherein both the first termination electrode and the second termination electrode are electrically connected to the channel stopper electrode.

7. The semiconductor device according to claim 1, wherein the second termination electrode is not electrically connected to the channel stopper electrode.

8. The semiconductor device according to claim 1, further comprising a second termination trench formed in the drift layer in the termination region,
wherein
the plurality of termination electrodes are also provided in the second termination trench while being surrounded by a second termination insulating film,
the channel stopper electrode is provided on the upper surface of the drift layer while being electrically connected to the channel stopper region, at least one of the termination electrodes in the first termination trench, and at least one of the termination electrodes in the second termination trench,
the plurality of termination electrodes in the second termination trench include a third termination electrode and a fourth termination electrode, and
the third termination electrode and the fourth termination electrode are provided apart from each other in the second termination trench.

9. The semiconductor device according to claim 8, wherein at least a part of the third termination electrode is provided so as to overlap the fourth termination electrode in plan view.

10. The semiconductor device according to claim 8, wherein
the second termination trench is formed at a position farther from the active region than the first termination trench, and
the second termination trench is formed deeper than the first termination trench.

11. The semiconductor device according to claim 1, wherein
the plurality of termination electrodes in the first termination trench further include a fifth termination electrode, and
the fifth termination electrode is provided apart from the first termination electrode and the second termination electrode in the first termination trench.

12. The semiconductor device according to claim 1, further comprising a protective film provided so as to cover the channel stopper electrode.

13. The semiconductor device according to claim 1, further comprising a charge accumulation region of the first conductivity type provided below the channel stopper region while being adjacent to the first termination trench,
wherein the charge accumulation region has an impurity concentration higher than that of the drift layer and lower than that of the channel stopper region.

14. A method of manufacturing a semiconductor device including an active region and a termination region surrounding the active region in plan view, comprising:
forming an impurity region of a second conductivity type on a surface layer of a drift layer of a first conductivity type in the active region;
forming a channel stopper region of the first conductivity type having an impurity concentration higher than that of the drift layer, on the surface layer of the drift layer in the termination region;
forming a gate trench in the drift layer at a position adjacent to the impurity region in the active region and forming a first termination trench in the drift layer in the termination region;
forming a gate insulating film and a first termination insulating film in the gate trench and the first termination trench, respectively;
forming a plurality of gate electrodes surrounded by the gate insulating film and a plurality of termination electrodes surrounded by the first termination insulating film in the gate trench and the first termination trench, respectively;
forming an interlayer insulating film covering the gate trench;
forming a channel stopper electrode electrically connected to the channel stopper region and at least one of the termination electrodes, on an upper surface of the drift layer;
forming an upper-surface electrode covering the upper surface of the drift layer and the interlayer insulating film; and
forming a lower-surface electrode on a lower surface of the drift layer at least in the active region,
wherein
the plurality of termination electrodes include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

15. A method of manufacturing a semiconductor device including an active region and a termination region surrounding the active region in plan view, comprising:
forming an impurity region of a second conductivity type on a surface layer of a drift layer of a first conductivity type in the active region;
forming a channel stopper region having an impurity concentration higher than that of the drift layer, on the surface layer of the drift layer in the termination region;
forming a gate trench in the drift layer at a position adjacent to the impurity region in the active region and forming a first termination trench in the drift layer in the termination region;
forming a gate insulating film and a first termination insulating film in the gate trench and the first termination trench, respectively;
forming a plurality of gate electrodes surrounded by the gate insulating film and a plurality of termination electrodes surrounded by the first termination insulating film in the gate trench and the first termination trench, respectively;
forming an interlayer insulating film covering the gate trench;
forming a channel stopper electrode electrically connected to the channel stopper region and at least one of the termination electrodes, on an upper surface of the drift layer;
forming an upper-surface electrode covering the upper surface of the drift layer and the interlayer insulating film; and
forming a lower-surface electrode on a lower surface of the drift layer at least in the active region,
wherein
the first termination trench is formed in the drift layer at a position closer to the active region than an outer end of the channel stopper region, the outer end being an end on a side opposite to the active region,
the plurality of termination electrodes include a first termination electrode and a second termination electrode,
the plurality of gate electrodes include a first gate electrode and a second gate electrode,
the first termination electrode and the second termination electrode are provided apart from each other in the first termination trench, and
the first gate electrode and the second gate electrode are provided apart from each other in the gate trench.

16. The method of manufacturing a semiconductor device according to claim 15, wherein
forming the plurality of termination electrodes includes forming the at least one termination electrode connected to the channel stopper electrode so as to include a connection portion provided so as to extend on the upper surface of the drift layer,
forming the channel stopper region includes forming the channel stopper region at a position farther from the active region than the connection portion, where the channel stopper region does not overlap the connection portion in plan view, and
regions of the same conductivity type in the active region and the channel stopper region are simultaneously activated after the plurality of termination electrodes are formed.
